(19) United States
(12) Patent Application Publication
(10) Pub. No.: US 2018/0293949 A1
(43) Pub. Date: Oct. 11, 2018

(54) DATA PROCESSING DEVICE CONNECTED WITH DISPLAY DEVICE AND CONTROL METHOD OF DISPLAY DEVICE

(71) Applicant: Sharp Kabushiki Kaisha, Sakai City, Osaka (JP)

(72) Inventors: Yousuke NAKAMURA, Sakai City (JP); Teruhisa MASUI, Sakai City (JP); Tatsuhiko SUYAMA, Sakai City (JP)

(73) Assignee: Sharp Kabushiki Kaisha, Osaka (JP)

(21) Appl. No.: 15/766,019

(22) PCT Filed: Oct. 12, 2016
(86) PCT No.: PCT/JP2016/080217

§ 371 Date: Apr. 5, 2018

(30) Foreign Application Priority Data
Oct. 19, 2015 (JP) 2015-205672

(51) Int. Cl. G09G 3/36; G09G 5/393; H01L 29/786

(52) U.S. Cl. CPC G09G 3/3648; G09G 5/393; G09G 2360/12; G09G 2300/0861; H01L 29/78693

(57) ABSTRACT

The present invention provides a data processing device connected with a display device performing intermission driving, in which power consumption of the display device is sufficiently reduced while securing high quality display by the display device. When a host shifts to Intermission State 2 together with an LCD without data updating in an image buffer in the host, the image buffer is extended (extended from 2 frames (A, B) to 4 frames (A-D)). Thereafter, when new display image data is supplied to the image buffer due to a user operation, a return instruction is transmitted from the host to the LCD. When stopped circuits in the LCD become operable, a return completion notification is sent from the LCD to the host. The host prevents frame missing by writing the new display image data into the image buffer in the extension state during the period of this returning, and transfers the new display image data to the LCD after receiving the return completion notification.

### TECHNICAL FIELD

The present invention relates to data processing devices connected with display devices which perform so called intermission driving, and to methods for controlling these display devices in these data processing devices.

### BACKGROUND ART

Power saving in liquid crystal display devices and other display devices is an ongoing challenge. Toward this end, Patent Document 1, for example, discloses a display device driving method in which a refreshing period during which a display image is refreshed by scanning gate lines that serve as scanning signal lines of the liquid crystal display device is followed by a non-refreshing period during which refreshing is stopped by bringing all of the gate lines into a non-scanning state. In this intermission period, it is possible not to supply signals such as control signals to, e.g., a gate driver which serves as a scanning signal line drive circuit and/or a source driver which serves as a data signal line drive circuit. This makes it possible to stop operation of the gate driver and/or the source driver, and therefore to reduce power consumption. The driving method in which a refreshing period is followed by a non-refreshing period (intermission period) as exemplified in Patent Document 1 is called “intermission driving” for example. The intermission driving is also called “low-frequency driving” or “intermittent driving”. Intermission driving as described above is suitable for displaying a still image. Inventions related to intermission driving are disclosed in Patent Document 2 and other publications as well as Patent Document 1.

In a display device in which intermission driving as described above is performed, display image is not refreshed for every frame period when there is no change in the image which is to be displayed. However, display image must be refreshed for every predetermined period which is longer than one frame period. If the display device is provided with a frame buffer which holds display image data to be used for the refreshing, it is possible to carry out the refreshing within the display device by internal operation. In many cases, however, the frame buffer is not provided within the display device for the sake of cost reduction, and in such a case, a frame buffer is provided in a main body of an electronic appliance that has the display device as a component. Hereinafter, such a configuration, in which a frame buffer is provided in the main body of the electronic appliance without providing a frame buffer in a display device, is referred to as “main body frame buffer configuration”.

### PRIOR ART DOCUMENTS

### Patent Documents

Patent Document 1: WO/2013/008668

Patent Document 2: WO/2013/140980

### SUMMARY OF THE INVENTION

### Problems to be Solved by the Invention

In the display device of the intermission driving type, the more the portion stopping operation in the non-refreshing period (hereinafter referred to as “intermission portion”), the greater the power consumption reduction effect becomes. However, when the number of intermission portions increases, the time required for the display device to return from the intermission state to the normal state becomes long. Therefore, when the number of intermission portions is increased, in the main body frame buffer configuration as described above, there may be a case where the image data for refreshing the display image is missing. That is, when updating of image data in the frame buffer of the main body is detected and image data for refreshing is sent to the display device, there may be a case where all the intermission portions of the display device can not return to the normal state and some thereof do not work. In this case, in the display device, image data for refreshing the display image is missing, and normal image display can not be performed.

In this regard, there is considered a method of suppressing the loss of image data by sending a return instruction to the normal state from the main body to the display device a predetermined time before updating the display image. However, in the case where unpredictable updating of image data occurs due to user's operation or the like, such a method can not be used. On the other hand, if the number of intermission potions in the display device is reduced in order to avoid such loss of image data, the effect of reducing power consumption by the intermission driving is small.

It is therefore an object of the present invention to provide a data processing device which is connected with an intermission driving display device and has a frame buffer, and is capable of achieving a satisfactory power saving by means of intermission driving while ensuring a high level of display quality of the display device.

### Solutions to the Problem

A first aspect of the present invention provides a data processing device connected data-exchangeably with a display device having an intermission driving mode, in which the display device drives a display section in such a manner that a refreshing period during which an image displayed in the display section is refreshed and a non-refreshing period during which an image displayed in the display section is not refreshed are alternated with each other, the data processing device including:

a memory section capable of storing image data for a plurality of frames each representing an image to be displayed in the display section, the memory section having, as an image buffer, a memory area including at least one frame buffer area;

an update detection section configured to detect a data update of image data in the image buffer, the data update being caused by writing of new image data into the image buffer; a data transfer controller configured to transfer image data stored in the image buffer to the display device by a first-in first-out method upon detection of a data update in the image buffer by the update detection section, and assume an intermission state for an intermission period determined as the non-refreshing period at most upon detection of a non-update of the image data in the image buffer for a predetermined period by the update detection section;

wherein the data transfer controller is configured to

extend the memory area of the memory section upon shifting to the intermission state, and

return to a normal state of transferring the image data to the display device in response to a data update by the update detection section as well as to send a return instruction for operating a stopped circuit in the display device to the display device, upon detection of a data update in the image buffer by the update detection section in the intermission state.

A second aspect of the present invention provides the data processing device according to the first aspect of the present invention, wherein, if the memory area of the image buffer has been extended, the data transfer controller counts as a non-update frame period count the number of frame periods during which the update detection section detects a non-update of the image data in the image buffer in the normal state, and releases an extension frame buffer area defined as an extension portion of the image buffer when the non-update frame period count becomes larger than the number of frame periods corresponding to a return time defined as time from sending of the return instruction to the display device till resuming of operation of the stopped circuit in the display device.

A third aspect of the present invention provides the data processing device according to the first aspect of the present invention, wherein the data transfer controller

sends a return instruction for operating the stopped circuit in the display device to the display device when the data transfer controller returns from the intermission state to the normal state,

transfers the image data in the image buffer to the display device at a second transfer rate higher than a first transfer rate predetermined as a standard rate when the data transfer controller receives a return completion notification indicating resumption of operation of the stopped circuit in the display device from the display device after sending the return instruction,

releases the extension frame buffer area and changes a transfer rate of the image data in the image buffer to the first transfer rate when there occurs a frame period in which image data stored in the extension frame buffer area has already been read out and new display image data has not been written into the extension frame buffer area, if the image data in the image buffer is transferred to the display device at the second transfer rate.

A fourth aspect of the present invention provides the data processing device according to the third aspect of the present invention, wherein, upon receiving the return completion notification from the display device, the data transfer controller transfers the image data in the image buffer to the display device at the second transfer rate for time corresponding to the number of frame periods given by the following equation:

Nfast=(Ffast*Ndelay)/(Ffast−Forig)

where Ffast is the second transfer rate, Forig is the first transfer rate, Ndelay is the number of frames for which a delay occurs due to the extension of the memory area of the image buffer causes delay.

A fifth aspect of the present invention provides the data processing device according to the first aspect of the present invention, wherein the data transfer controller

sends a return instruction for operating the stopped circuit in the display device to the display device, upon returning from the intermission state to the normal state,

determines a return time measurement value by measuring time from sending the return instruction till receiving a return completion notification indicating resumption of operation of the stopped circuit in the display device, and determines or changes a size of the extension frame buffer area, upon receiving the return completion notification after sending the return instruction.

A sixth aspect of the present invention provides the data processing device according to the fifth aspect of the present invention, wherein, when the data transfer controller sends the return instruction to the display device after determining the return time measurement value, the data transfer controller starts transferring the image data in the image buffer to the display device at timing based on the return time measurement value without waiting for the return completion notification to be received from the display device after sending the return instruction.

A seventh aspect of the present invention provides the data processing device according to the first aspect of the present invention, wherein the data transfer controller

determines the intermission period based on refreshing-related information obtained from the display device, when the update detection section detects a non-update of the image data in the image buffer for the predetermined period,

shifts to the intermission state if the intermission period is longer than a predetermined reference period,

stops a first circuit defined as a circuit which has time required for resuming operation not longer than a predetermined time among circuits to be stopped in the display device in the intermission state and thereafter shifts to a short intermission state different from the intermission state without extending the memory area of the image buffer, if the intermission period is not longer than the predetermined reference period, and

returns to the normal state and resumes operation of the first circuit in the display device, when the update detection section detects a data update in the image buffer while the data transfer controller is in the short intermission state.

A eighth aspect of the present invention provides the data processing device according to the first aspect of the present invention, wherein the data transfer controller includes:

a first interface circuit configured to transfer image data in the image buffer to the display device, and

a second interface circuit configured to send a return instruction for operating the stopped circuit in the display device to the display device and receive a return completion notification indicating resumption of operation of the stopped circuit in the display device from the display device, when the data transfer controller returns from the intermission state to the normal state,

wherein the second interface circuit is provided as a serial interface having a slower data transfer rate than the first interface circuit.

A ninth aspect of the present invention provides the data processing device according to any one of the first through eighth aspects of the present invention, wherein the display section includes a thin film transistor having a channel etch structure which has a channel layer formed of an oxide semiconductor, as a switching element for forming each pixel constituting an image to be displayed.

A tenth aspect of the present invention provides a method for enabling a data processing device to control a display device which is connected data-exchangeably therewith and has an intermission driving mode, in which the display device drives a display section in such a manner that a refreshing period during which an image displayed in the display section is refreshed and a non-refreshing period during which an image displayed in the display section is not refreshed are alternated with each other, the method including:

an update detection step of detecting an update of image data in an image buffer in a memory section within the data processing device, the memory section being capable of storing image data for a plurality of frames each representing an image to be displayed in the display section, the memory section having, as the image buffer, a memory area including at least one frame buffer area;

an updated-data transfer step of transferring image data stored in the image buffer to the display device by a first-in first-out method, upon detection of a data update in the image buffer;

an intermission step of assuming an intermission state for an intermission period determined as the non-refreshing period at most upon detection of a non-update of the image data in the image buffer for a predetermined period;

a buffer extension step of extending the memory area of the image buffer upon shifting to the intermission state;

a return instruction step of sending a return instruction for operating a stopped circuit in the display device to the display device, upon detection of a data update in the image buffer in the intermission state; and

a return-to-normal-state step of returning to a normal state, in which the image data is transferred to the display device in response to a data update in the update detection step, upon detection of a data update in the image buffer in the intermission state.

A eleventh aspect of the present invention provides a device driver program for enabling a data processing device to control a display device which is connected data-exchangeably therewith and has an intermission driving mode, in which the display device drives a display section in such a manner that a refreshing period during which an image displayed in the display section is refreshed and a non-refreshing period during which an image displayed in the display section is not refreshed are alternated with each other, the program causing a processor in the data processing device to execute:

an update detection step of detecting an update of image data in an image buffer in a memory section within the data processing device, the memory section being capable of storing image data for a plurality of frames each representing an image to be displayed in the display section, the memory section having, as the image buffer, a memory area including at least one frame buffer area;

an updated-data transfer step of transferring image data stored in the image buffer to the display device by a first-in first-out method, upon detection of a data update in the image buffer;

an intermission step of assuming an intermission state for an intermission period determined as the non-refreshing period at most upon detection of a non-update of the image data in the image buffer for a predetermined period;

a buffer extension step of extending the memory area of the image buffer upon shifting to the intermission state;

a return instruction step of sending a return instruction for operating a stopped circuit in the display device to the display device, upon detection of a data update in the image buffer in the intermission state; and

a return-to-normal-state step of returning to a normal state, in which the image data is transferred to the display device in response to a data update in the update detection step, upon detection of the data update in the image buffer in the intermission state.

A twelfth aspect of the present invention provides a computer-readable recording medium containing the program according to the eleventh aspect.

Other aspects of the present invention are clear from the above description of the first through the twelfth aspects of the present invention and from description of each embodiment to be made herein later, and therefore will not be stated here.

### Advantages of the Invention

According to the first aspect of the present invention, in a data processing device as a host to which a display device performing an intermission driving is connected, when it is detected that image data in an image buffer is not updated for a predetermined period, a data transfer controller assumes an intermission state for an intermission period determined at most as a non-refreshing period in the intermission driving mode. In the intermission state, power consumption in the display device as well as in the host side is reduced by stopping operation of a predetermined circuits in the display device. Upon shifting to such an intermission state, a memory area of the image buffer is extended in the display device. Therefore, even in the case where it takes time to resume operation of the stopped circuit in the display device when returning from the intermission state to the normal state, it is possible to avoid loss of the image data (frame missing) by stopping transfer of the image data from the host to the display device and writing new image data into the image buffer during the returning period. As a result, even in the case where it is impossible to predict the returning point from the intermission state to the normal state, such as when a data update occurs in the image buffer due to a user operation on the data processing device, it is possible to greatly reduce power consumption without degrading the display quality, by stopping many circuits within the display device in the intermission state with preventing frame missing.

According to the second aspect of the present invention, if the memory area of the image buffer has been extended, an extension frame buffer area defined as an extension portion of the image buffer is released when the non-update frame period count becomes larger than the number of frame periods corresponding to a return time of the display device in the normal state. Therefore, it is possible to avoid consuming extra memory in the host in order to prevent frame missing.

According to the third aspect of the present invention, the image data in the image buffer is transferred to the display device at a higher rate than a standard rate when the data transfer controller returns from the intermission state to the normal state, and thereby the memory area of the image buffer which has been extended upon shifting to the intermission state (extension frame buffer area) becomes releasable. Therefore, even in the case of continuing data update in the image buffer, such as in the case of reproducing a moving image, it is possible to certainly release the extension frame buffer area and eliminate delay in refreshing the display image, after a predetermined time since the display device returns to the normal state.

According to the fourth aspect of the present invention, the image data in the image buffer is transferred to the display device at a high speed for time corresponding to the predetermined number of frame periods Nfast=(Ffast*Ndelay)/(Ffast−Forig) when the data transfer controller receives the return completion notification from the display device, and thereby the extension frame buffer area becomes releasable. Therefore, the same advantages as the above third aspect are obtained.

According to the fifth aspect of the present invention, a return time measurement value is determined by measuring time from sending the return instruction till receiving the return completion notification, and a size of the extension frame buffer area is determined based on the return time measurement value. Therefore, it is possible to certainly prevent frame missing in the returning state of the display device without allocating extra memory for the extension frame buffer area.

According to the sixth aspect of the present invention, when the return instruction is sent to the display device after determining the return time measurement value, transfer of the image data in the image buffer to the display device is started at timing based on the return time measurement value without waiting for the return completion notification to be received from the display device after sending the return instruction. This simplifies the operation and configuration for returning from the intermission state to the normal state and makes it possible to reduce delay in refreshing the displayed image.

According to the seventh aspect of the present invention, when it is detected that the image data in an image buffer is not updated for a predetermined period, the data transfer controller shifts to a short intermission state different from the intermission state if the intermission period determined based on refreshing-related information obtained from the display device is not longer than a predetermined reference period, and shifts to the intermission state for stopping many circuits in the display device if the intermission period is longer than the predetermined reference period. In the intermission state, although the power consumption of the display device can be greatly reduced, it takes time to return from the intermission state to the normal state, which causes delay in refreshing the displayed image. Therefore, in the short intermission state, in which the intermission period is comparatively short, it is possible to return to the normal state so as to display a changed image quickly when there is any change found in the image to be displayed, while in the intermission state, in which the intermission period is comparatively long, it is possible to reduce the power consumption of the display device more greatly than in the short intermission state by assuming that the necessity for returning to the normal state is low and stopping many circuits in the display device.

According to the eighth aspect of the present invention, the data transfer controller is provided with, in addition to a first interface circuit which is for transferring image data from the image buffer to the display device, a second interface circuit which is provided as a serial interface having a slower data transfer rate than the first interface, for data exchange between the data processing device as a host and the display device. The second interface circuit is used for sending the return instruction to the display device and receiving the return completion notification indicating resumption of operation of the stopped circuit in the display device. The arrangement decreases power consumption for data transfer between the data processing device and the display device through selective use of the first interface circuit and the second interface circuit as described, depending on the amount of data transfer.

According to the ninth aspect of the present invention, since the display section of the display device employs a thin film transistor having a channel etch structure which has a channel layer formed of an oxide semiconductor, as a switching element for forming each pixel, off-leak current of the thin film transistor is greatly reduced and the intermission driving can be satisfactorily performed.

Advantages provided by other aspects of the present invention will be clear from the first through the ninth aspects of the present invention and from description of the embodiments to be given below, and therefore will not be stated here.

### BRIEF DESCRIPTION OF DRAWINGS

FIG. 1 is a block diagram which shows a configuration of a portable terminal as an electronic appliance incorporating a data processing device according to a first embodiment of the present invention.

FIG. 2 is a block diagram which shows a system configuration of the data processing device according to the first embodiment, with a display device connected therewith.

FIG. 3 is a block diagram which shows a detailed configuration of the display device connected with the data processing device according to the first embodiment.

FIG. 4 is a signal waveform chart for describing operation of the display device in an intermission driving mode.

FIG. 5 is a block diagram which shows a configuration of a display control circuit in the display device connected with the data processing device according to the first embodiment.

FIG. 6 is a block diagram for describing writing and reading of display image data into and from an unextended image buffer in the first embodiment.

FIG. 7 is a block diagram for describing writing and reading of display image data into and from an image buffer in an extension state in the first embodiment.

FIG. 8 is a flowchart which shows a processing procedure of an interrupt handler for implementing an update detection section included in a video driver in the first embodiment.

FIG. 9 is a flowchart which shows a processing procedure, under Normal State, of a program for implementing a DSI controller included in the video driver in the first embodiment.

FIG. 10 is a flow chart which shows a processing procedure, under an intermission state, of a program for implementing the DSI controller included in the video driver in the first embodiment.

FIG. 11 is a block diagram for describing power saving in the display device connected with the data processing device according to the first embodiment.

FIG. 12 consists of a sequence diagram (A) for describing operation in the first embodiment when the host assumes Intermission State 1, and a sequence diagram (B) for describing operation when the host assumes Intermission State 2.

FIG. 13 is a timing chart which shows operation related to update and transfer of display image data in an image buffer non-extended configuration.

FIG. 14 is a timing chart which shows operation related to update and transfer of display image data in the first embodiment.

FIG. 15 is a timing chart which shows operation related to release of an extension state of the image buffer in the first embodiment.

FIG. 16 is a sequence diagram and timing chart which shows an operation example according to the first embodiment.

FIG. 17 is a diagram which shows power saving performance according to the first embodiment.

FIG. 18 is a block diagram which shows a system configuration of a data processing device according to a second embodiment of the present invention, with a display device connected therewith.

FIG. 19 is a sequence diagram which shows an operation example according to the second embodiment.

FIG. 20 is a sequence diagram for describing operation right after an initialization sequence according to a third embodiment of the present invention.

FIG. 21 is a sequence diagram which shows an operation example according to the third embodiment.

FIG. 22 consists of a timing chart (A) showing operation for determining a size of an extension portion of the image buffer by a first method, and a timing chart (B) showing operation for determining a size of an extension portion of the image buffer by a second method.

FIG. 23 is a timing chart which shows operation relating to release of an extension state of an image buffer in a fifth embodiment of the present invention

FIG. 24 is a flow chart which shows a processing procedure, under Normal State, of a program for implementing a DSI controller included in a video driver according to the fifth embodiment.

FIG. 25 is a flowchart which shows a processing procedure, under an intermission state, of a program for implementing the DSI controller included in the video driver according to the fifth embodiment.

FIG. 26 is a flowchart which shows a processing procedure, under an intermission state, of a program for implementing a DSI controller included in a video driver according to a sixth embodiment of the present invention.

### MODES FOR CARRYING OUT THE INVENTION

Hereinafter, embodiments of the present invention will be described with reference to the attached drawings. Hereinafter, the term one frame period means a period for refreshing one screen (redrawing a displayed image), and the length of “one frame period” is assumed as long as a commonly utilized length of one frame period (16.67 ms) used in display devices of a refreshing rate of 60 Hz. However, the present invention is not limited to this.

### 1. First Embodiment

### 1.1 Overall Configuration and Operation Outline

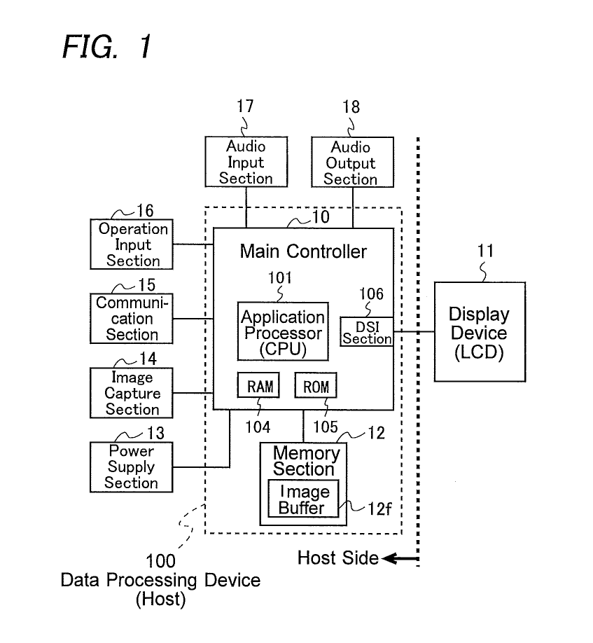

FIG. 1 is a block diagram which shows a configuration of a portable terminal as an electronic appliance which makes use of a data processing device according to a first embodiment of the present invention. This portable terminal is configured, specifically, as a smartphone, tablet-type terminal, mobile telephone, PDA (Personal Digital Assistance), lap-top type personal computer or portable game console.

As shown in FIG. 1, the portable terminal includes a main controller 10, a display device 11, a memory section 12, a power supply section 13, an image capture section 14, a communication section 15, an input operation section 16, an audio input section 17, and an audio output section 18. The present invention has characteristics which are related to operation of the display device 11 and from this point of view, description hereinafter will use a term data processing device 100 or a host 100 as a component including the main controller 10 which the display device 11 is connected with, and the memory section 12; and in the following description, the portable terminal representing an electronic appliance will be viewed as divided into a host side and a display device side.

The main controller 10 performs procedures and controls necessary for implementing various functions incorporated in the portable terminal, and includes an application processor provided by a central processing device (hereinafter may also be called “CPU”) 101, a RAM (Random Access Memory) 104, and a ROM (Read Only Memory) 105. In other words, the CPU 101 executes programs (such as an operating system 130 which will be described later) stored in the ROM 105 in the main controller 10, thereby performing desired procedures and controls on relevant components to implement various functions of the portable terminal. The main controller 10 also includes a DSI section 106 as a host-side interface circuit for making data exchange with the display device 11 via an interface conforming to DSI (Display Serial Interface) Standards proposed by MIPI (Mobile Industry Processor Interface) Alliance (hereinafter called “MIPI-DSI Standards”).

The input operation section 16 is a section for receiving inputting operations from a user of this portable terminal, and is implemented by a touch panel and so on. The communication section 15 provides the portable terminal with wireless data exchange capability with other portable terminals. The image capture section 14 uses an image sensor to capture images of people and things and supply image signals to the main controller 10. The audio input section 17 captures ambient sounds and supply these audio signals to the main controller 10. The audio output section 18 outputs sounds based on audio data supplied from the main controller 10. The memory section 12 is provided by a memory of a greater capacity than the RAM 104, the ROM 105, etc. which are in the main controller 10, and includes memory areas to be used as an image buffer 12f which is to be described later. The display device 11 displays images represented by image data supplied from the main controller 10. The power supply section 13 supplies electric power necessary for operation of each section in the portable terminal.

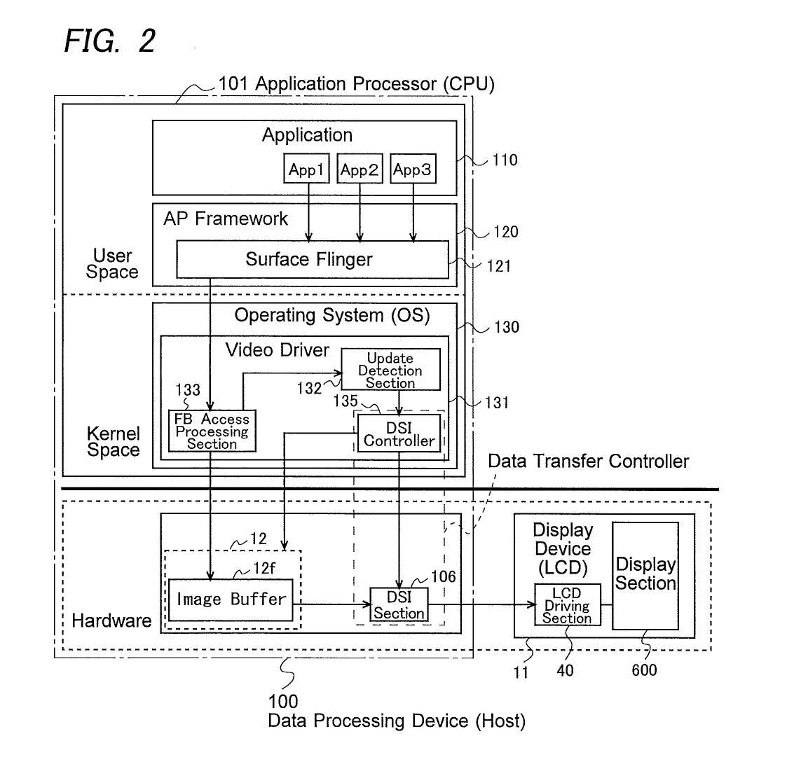

FIG. 2 is a block diagram which shows a system configuration (hardware and software configurations) of the data processing device 100 according to the present embodiment, with the display device 11 connected therewith. The application processor (CPU) 101 may be provided by a single, independent IC chip, or a single CPU or a plurality of CPUs (multi-core processor) included in a system-on-chip type IC chip which includes one or more CPUs. In the present embodiment, the CPU 101 executes predetermined programs, whereby an operating system (hereinafter abbreviated as “OS”) 130, which has process management capabilities, works in the kernel space, and an application frame work (hereinafter called “AP frame work”) 120, which utilizes functions provided by the OS 130 thereby providing necessary functions for an application 110, works in the user space. The application 110 includes individual applications App1, App2, App3. Each individual application implements their functions intended to offer to the user by utilizing the functions of the AP frame work 120 as corresponding programs are executed by the CPU 101. It should be noted here that the OS 130 provides system functions (“signal”, “wait”, etc.) for synchronization between processes or threads operating on the CPU 101, and system functions for allocating and releasing memory areas in the memory section 12, i.e. memory management function (system functions for realizing functions such as malloc and free).

The OS 130 includes a video driver 131 as a device driver to control hardware for displaying images in the display device 11. The video driver 131 has an FB access processing section 133 and a DSI controller 135 for respectively controlling an image buffer 12f and a DSI section 106 in the data processing device (host) 100. The DSI section 106 which serves as an interface circuit and a DSI controller 135 which serves as an interface controller constitute a data transfer controller. The image buffer 12f is a memory for storing data (hereinafter called “display image data”) which represents an image to be displayed in the display device 11. The FB access processing section 133 controls updating (writing) of the display image data in the image buffer 12f. By using a video mode of the MIPI-interface which conforms to DSI Standards (hereinafter called “DSI video mode”), the DSI section 106 is capable of transferring a data DAT, which includes one frame-amount of display image data in the image buffer 12f, to the display device 11 for each frame period (16.67 ms) (this applies to all the other embodiments, too). The DSI controller 135 can stop and resume the transfer of the data DAT from the DSI section 106 to the display device 11. It should be noted here that for operation of the DSI controller 135, the video driver 131 further has an update detection section 132 which detects whether or not the display image data in the image buffer 12f is updated by the FB access processing section 133. Detailed operation of the update detection section 132 and the DSI controller 135 will be described later.

The display device 11 connected with the data processing device according to the present embodiment is an LCD module (hereinafter, may also simply called “LCD”) and has a display section 600 which makes use of liquid crystal and an LCD driving section 40. The LCD driving section 40 is connected with the data processing device 100 (i.e., DSI section 106 therein), is capable of exchanging data therewith via the interface conforming to the above-described MIPI-DSI Standards, and drives the display section 600 based on the data DAT received from the host, i.e., the data processing device 100, thereby displaying an image represented by the display image data contained in the data DAT, in the display section 600 (details will be described later).

With the configuration described above and depicted in FIG. 2, each application Appi (i=1, 2, 3, . . . ) can update an image which is displayed in the display section 600 of the display device 11 by updating display image data in the image buffer 12f by means of the FB access processing section 133 via a surface flinger 121 in the AP frame work 120 (Details will be described later). The surface flinger 121 is a component for execution and management of image drawing in the screen, and assigns a drawing area (called “surface”) to each application. Once all of the applications complete writing of data to respective surfaces, the surface flinger 121 generates data for display in the screen by combining these surfaces, and write the generated data into the image buffer 12f by using the FB access processing section 133.

The above-described operations and functions of the constituent elements 132 through 135 in the video driver 131 are implemented by the CPU 101 executing programs (hereinafter called “LCD device driver program”) for the video driver 131. The LCD device driver program is installed in the ROM 105, for example, which serves as a storage medium readable by the CPU 101, before the manufacturer of the portable terminal shown in FIG. 1 ships the product. Alternatively, the LCD device driver program may be recorded and offered in the form of portable recording media such as CD-ROM (Compact Disc Read Only Memory), USB memory (USB (Universal Serial Bus) flash drive), etc., for installation to the ROM 105, etc., in the portable terminal from these portable recording media, via an unillustrated interface (not illustrated) of the portable terminal in FIG. 1. Further, the LCD device driver program may be provided from a predetermined external server via a network accessible by the portable terminal and then via the communication section 15 for installation to the ROM 105, etc., in the portable terminal.

### 1.2 Display Device Configuration

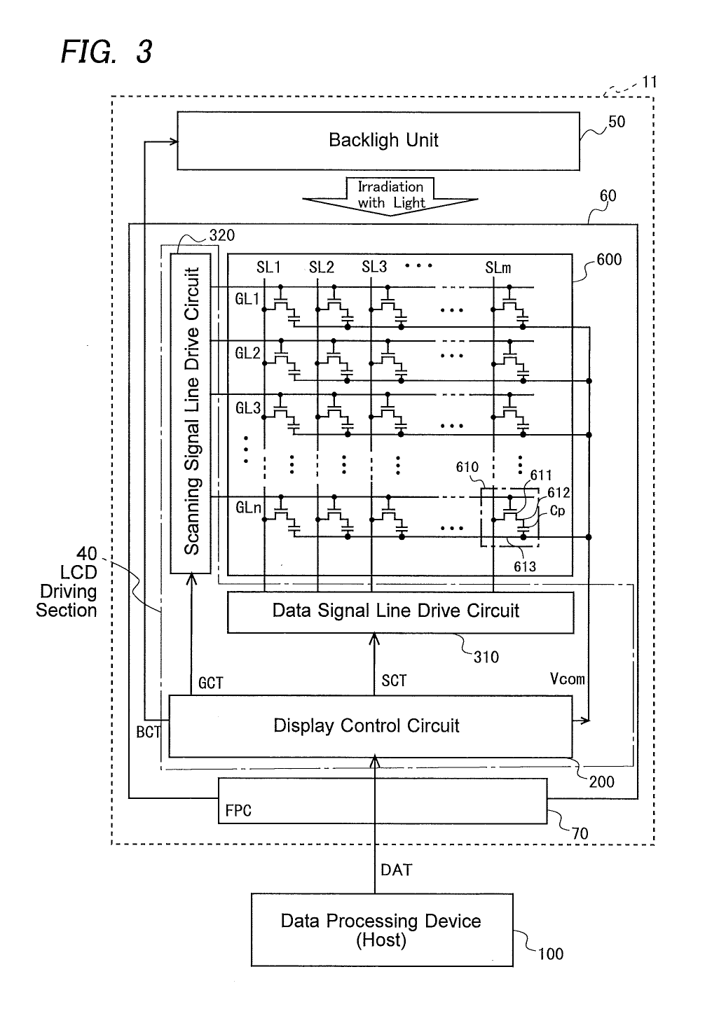

FIG. 3 is a block diagram which shows a configuration of the display device 11 connected with the data processing device according to the present embodiment. As has been described, the display device 11 is an LCD module, and has a liquid crystal display panel 60 and a backlight unit 50. The liquid crystal display panel 60 is attached to an FPC (Flexible Printed Circuit) 70 for external connection. On the liquid crystal display panel 60, there are provided the display section 600, a display control circuit 200, a data signal line drive circuit 310, and a scanning signal line drive circuit 320. The data signal line drive circuit 310, the scanning signal line drive circuit 320 and the display control circuit 200 constitute the LCD driving section 40 described earlier (see FIG. 2). One or both of the data signal line drive circuit 310 and the scanning signal line drive circuit 320 may be provided within the display control circuit 200. Also, one or both of the data signal line drive circuit 310 and the scanning signal line drive circuit 320 may be formed integrally with the display section 600.

The display section 600 is formed with a plurality (m) of data signal lines SL1 through SLm, a plurality (n) of scanning signal lines GL1 through GLn, and a plurality (m×n) of pixel formation portions 610 disposed correspondingly to intersections made by the m data signal lines SL1 through SLm and the n scanning signal lines GL1 through GLn. Hereinafter, if these m data signal lines SL1 through SLm are not differentiated from each other, they will simply be called “data signal line SL”, and if these n scanning signal lines GL1 through GLn are not differentiated from each other, they will simply be called “scanning signal lines GL”. The m×n pixel formation portions 610 are formed in a matrix pattern. Each pixel formation portion 610 is constituted by: a TFT 611 which serves as a switching element having its gate terminal, serving as a control terminal, connected to a scanning signal lines GL that passes through a corresponding one of the intersections while having its source terminal connected to the data signal lines SL that passes said intersection; a pixel electrode 612 connected to a drain terminal of the TFT 611; a common electrode 613 provided commonly to the plurality of pixel formation portions 610; and a liquid crystal layer which is sandwiched between the pixel electrode 613 and the common electrode 113 and is common to these pixel formation portions 110. In the above, the pixel electrode 612 and the common electrode 613 form a liquid crystal capacitance, which functions as a pixel capacitance Cp. It should be noted here that typically, an auxiliary capacitance is provided in parallel to the liquid crystal capacitance for ensured voltage holding at the pixel capacitance Cp. Therefore, the pixel capacitance Cp is actually constituted by the liquid crystal capacitance and the auxiliary capacitance.

In the present embodiment, the TFT 611 is provided by a TFT which includes an oxide semiconductor layer as its channel layer (hereinafter called “oxide TFT”) and has a channel etch structure. In this channel-etch-structure TFT, the source electrode and the drain electrode are disposed on the oxide semiconductor layer, at a space from each other, to sandwich a channel region of the transistor, with the source electrode and the drain electrode having their mutually opposed ends in contact with the oxide semiconductor layer. In other words, the source electrode and the drain electrode are disposed to make contact with an upper surface of the oxide semiconductor layer. The oxide semiconductor layer includes an In—Ga—Zn—O semiconductor (oxide semiconductor of an indium, gallium and zinc). It should be noted here that the oxide semiconductor layer may have a laminated structure including two or more layers.

An In—Ga—Zn—O semiconductor includes a ternary oxide containing In (indium), Ga (gallium) and Zn (zinc). There is no specific limitation to proportion (ratio) between In, Ga and Zn, so the ratio may be In:Ga:Zn=2:2:1, In:Ga:Zn=1:1:1, In:Ga:Zn=1:1:2, and so on. In the present embodiment, a semiconductor film which contains In, Ga and Zn at a ratio of 1:1:1 is utilized. A TFT, which includes an In—Ga—Zn—O semiconductor layer, has a high mobility (greater than 20 times as compared to those which make use of an amorphous silicon in its channel layer, or those called a-SiTFT) and low leak current (smaller than 1/100 as compared to an a-SiTFT); and therefore, is suitable as a driving TFT and a pixel TFT. Use of TFT which includes an In—Ga—Zn—O semiconductor layer makes it possible to dramatically reduce power consumption in a display device.

The oxide semiconductor layer may be made from whichever one of amorphous, crystalline and microcrystalline materials. If the oxide semiconductor layer has a laminated layer structure, these materials may be used in whichever combinations. When crystalline In—Ga—Zn—O semiconductors are utilized, it is preferable that the crystalline In—Ga—Zn—O semiconductors have their c axis substantially vertical to the layer surface. Crystal structures of the In—Ga—Zn—O semiconductors described above are disclosed in JP-A 2012-134475 Gazette. The entire contents disclosed in JP-A 2012-134475 Gazette are incorporated herein by reference.

The oxide semiconductor layer may include other oxide semiconductors in place of the In—Ga—Zn—O semiconductors. For example, the layer may contain In (indium), Sn (tin), Zn (zinc) in the form of an In—Sn—Zn—O semiconductor (such as In₂O₃—SnO₂—ZnO). Other examples include Zn—O semiconductors (ZnO), In—Zn—O semiconductors, Zn—Ti—O semiconductors, Cd—Ge—O semiconductors, Cd—Pb—O semiconductors, CdO (Cadmium oxide), Mg—Zn—O semiconductors, and In—Ga—Sn—O semiconductors. It should be noted here that use of an oxide TFT as the TFT 611 represents one example; a silicon TFT may be used instead.

The display control circuit 200 is implemented typically as an IC (Integrated Circuit). The display control circuit 200 receives data DAT from the host 100 via an FPC 70, and in response to this, generates and outputs a data-side control signal SCT, a scanning-side control signal GCT, and a common voltage Vcom. The data-side control signal SCT is supplied to the data signal line drive circuit 310. The scanning-side control signal GCT is supplied to the scanning signal line drive circuit 320. The common voltage Vcom is supplied to the common electrode 613. In the present embodiment sending/receiving of the data DAT between the host 100 and the display control circuit 200 is performed via an interface which conforms to MIPI-DSI Standards as has been described. The interface conforming to MIPI-DSI Standards enables high-speed data transfer.

The data signal line drive circuit 310 generates and outputs data signal to be supplied to the signal lines SL, based on the data-side control signal SCT. The data-side control signal SCT contains, for example, a digital image signal corresponding to RGB data RGBD, a source start pulse signal, a source clock signal, a latch strobe signal, and a polarity switching signal. In accordance with the source start pulse signal, the source clock signal and the latch strobe signal, the data signal line drive circuit 310 operates its unillustrated shift register, sampling latch circuit, etc., obtains digital signals based on the digital image signal, converts the obtained digital signals with an unillustrated DA conversion circuit, and thereby generates data signals.

The scanning signal line drive circuit 320 repeats application of active scanning signals to the scanning lines GL in accordance with the scanning-side control signal GCT at a predetermined cycle. The scanning-side control signal GCT contains, for example, a gate clock signal and a gate start pulse signal. The scanning signal line drive circuit 320 operates its unillustrated shift register, etc. in accordance with the gate clock signal and gate start pulse signal, and thereby generates scanning signals.

The backlight unit 50 is on a back side of the liquid crystal display panel 60, and irradiate the back surface of the liquid crystal display panel 60 with backlight. The backlight unit 50 typically includes a plurality of LEDs (Light Emitting Diodes). The backlight unit 50 may be controlled by the display control circuit 200, or controlled by other method. If the liquid crystal display panel 60 is of a reflection type, then it is not necessary to have the backlight unit 50.

As described above, the data signals are applied to the data signal lines SL, the scanning signals are applied to the scanning signal lines GL and the backlight unit 50 is driven, whereby an image represented by display image data sent from the host 100 is displayed in the display section 600 of the liquid crystal display panel 60.

### 1.3 Intermission Driving

The display device 11 which is connected with a data processing device according to the present embodiment has a normal driving mode and an intermission driving mode as driving modes of the display section 600. In the normal driving mode, the display device 11 repeats sequential scanning of the scanning signal lines GL1 through GLn using one frame period (1 vertical scanning period) as a cycle while driving the data signal lines SL1 through SLm, whereby a display image in the display section 600 is refreshed every frame period.

In the intermission driving mode, on the other hand, the display control circuit 200 controls the data signal line drive circuit 310 and the scanning signal line drive circuit 320 in such a manner that that a refreshing period (hereinafter may also called “RF period”) in which a display image is refreshed and a non-refreshing period (hereinafter also called NRF period”) in which all the scanning signal lines GL1 through GLn are brought into a de-selected state are alternated with each other.

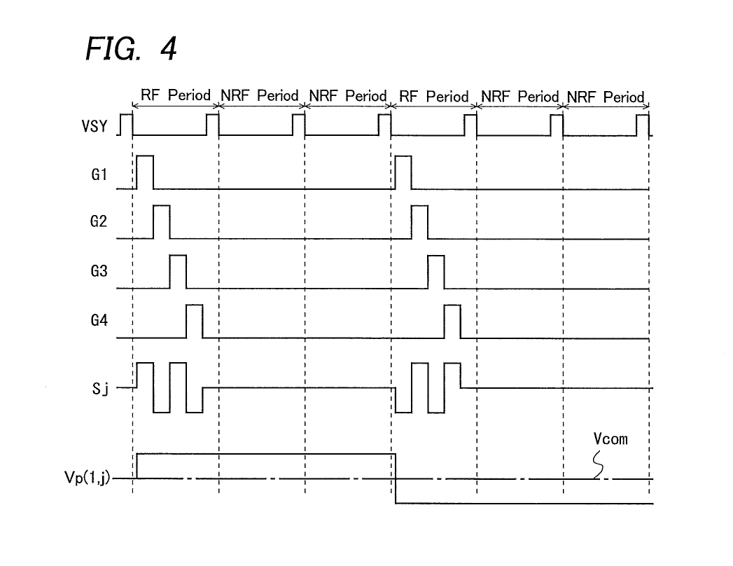

FIG. 4 is a signal waveform chart for describing an operation of the display device 11 in an intermission driving mode. For descriptive convenience, FIG. 4 assumes the number of scanning signal lines, as n=4. In the present embodiment, a pixel voltage which is held as a pixel data at a pixel capacitance Cp in each of the pixel formation portions 610 is re-written at a predetermined cycle (see FIG. 3) whenever an image is displayed in the display section 600. In other words, a display image in the display section 600 is refreshed at a predetermined cycle. In the present embodiment, the refreshing cycle is made of three frame periods, composed of one frame period as the refreshing period, and two frame periods that follow as the non-refreshing periods. As shown in FIG. 4, during the refreshing period (RF period), scanning signals G1 through G4 which are applied to the scanning signal lines GL1 through GL4 sequentially become active (HIGH level), while in each data signal line SLj, polarity of data signal Sj is inverted for each horizontal period (j=1, 2, . . . , m). During the non-refreshing period (NRF period), all of the scanning signals G1 through G4 are inactive. FIG. 4 also shows a waveform of the voltage Vp (1, j) at a pixel formation portion 610 in the first row of the j-th column which is connected with the scanning signal line GL1 and the data signal line SLj, together with the common voltage Vcom. Since the refreshing cycle is made of 3 frame periods as described earlier, the polarity of the pixel voltage Vp(1, j) with respect to the common voltage Vcom as a baseline is inverted for every three frame periods as shown in FIG. 4 (this also applies to pixel electrode polarity in other pixel formation portions).

As has been described, “one frame period” is a period for refreshing one screen, and the length of one frame period in the present embodiment is equal to a commonly utilized length of one frame period (16.67 ms) used in display devices of a refreshing rate of 60 Hz. In FIG. 4, each frame period is defined by a vertical synchronization signal VSY which assumes HIGH level for each frame period. The refreshing cycle in the present embodiment may be made of any number of periods as far as it is not shorter than two frame periods; a specific number thereof is determined with consideration to, e.g., how often the display section 600 will experience the image to be displayed therein (this also applies to all the other embodiments which will be described later). For example, the refreshing cycle may be 60 frame periods consisting of one frame period as the refreshing period and 59 frame periods that follow as the non-refreshing period. In this case, the refreshing rate is 1 Hz. Also, the refreshing period may be two frame periods or longer (the same applies to the other embodiments which will be described later).

### 1.4 Display Control Circuit Configuration

Next, a configuration of the display control circuit 200 will be described. The display control circuit 200 in the display device 11 connected with the data processing device according to the present embodiment utilizes a DSI video mode and does not have a RAM which serves as a frame buffer.

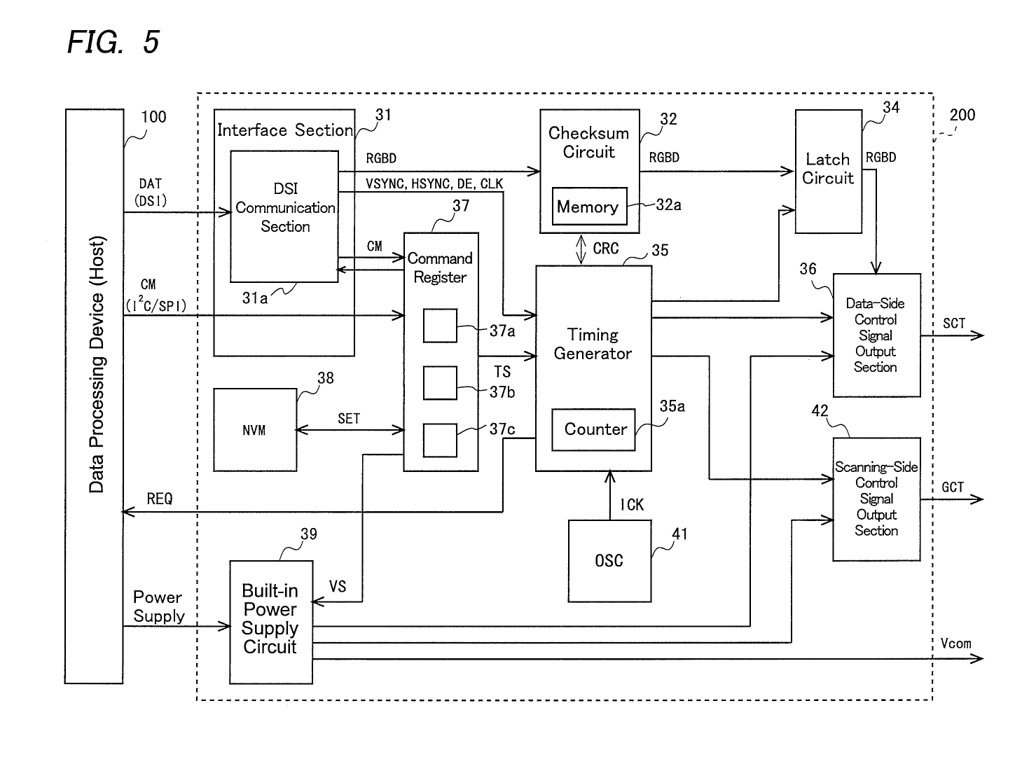

FIG. 5 is a block diagram which shows a configuration of the display control circuit 200. The display control circuit 200 includes an interface section 31, a command register 37, an NVM (Non-volatile memory) 38, a timing generator 35, an OSC (Oscillator) 41, a checksum circuit 32, a latch circuit 34, a built-in power supply circuit 39, a data-side control signal output section 36, and a scanning-side control signal output section 42. The interface section 31 includes a DSI communication section 31a which conforms to MIPI-DSI Standards, whereas the checksum circuit 32 includes a memory 32a. Also, the timing generator 35 includes a counter 35a, and the command register 37 includes registers 37a through 37c.

The DSI communication section 31a which conforms to MIPI-DSI Standards receives data DAT from the host 100 in the video mode. The data DAT contains RGB data RGBD which represents image-related data, a vertical synchronization signal VSYNC and horizontal synchronization signal HSYNC serving as synchronization signals, a data enable signal DE, a clock signal CLK and command data CM. The command data CM contains data related to various controls. Upon receiving the data DAT from the host 100, the DSI communication section 31a supplies the RGB data RGBD which is contained in the data DAT to the latch circuit 34 via the checksum circuit 32; supplies the vertical synchronization signal VSYNC, the horizontal synchronization signal HSYNC, the data enable signal DE, and the clock signal CLK to the timing generator 35, and supplies the command data CM to the command register 37. It should be noted here that the command data CM may be sent from the host 100 to the command register 37 via an interface which conforms to I2C (Inter Integrated Circuit) Standards or SPI (Serial Peripheral Interface) Standards. In this case, the interface section 31 includes a receiver section which conforms to I2C Standards or SPI Standards. The RGB data RGBD will also be called “image data”; the vertical synchronization signal VSYNC, the horizontal synchronization signal HSYNC, the data enable signal DE, and other signals may be collectively called “timing signals”.

The interface section 31 is configured to transfer information which is related to LCD driving and is held in the display control circuit 200, to the data processing device 100, i.e., to the host, via the interface conforming to MIPI-DSI Standards or an interface conforming to I2C Standards or SPI Standards, upon issuance of a predetermined command from the host. Examples of the information include counter values such as a non-refreshing count which will be described later, a polarity imbalance count, and command data such as non-refreshing frame count NREF which will be described later. Further, the interface section 31 is configured to stop or start specific circuits within the display control circuit 200 upon issuance of a predetermined command from the host, and turn off power supply to said specific circuits. For example, when a command instructing a return from Intermission State 2 to be described later to Normal State is issued from the host as the predetermined command, the interface section 31 starts the stopped circuits (not only first circuits but also second circuits which will be described later), and sends a return completion notification to the host at the time when resumption of operation of the circuits being stopped is confirmed.

In addition, the interface section 31 measures time (hereinafter referred to as “return time”) from receiving of the return instruction to the sending of the return completion notification, and holds this as a return time measurement value in the command register 37. When the power is turned off, the return time measurement value is stored in an NVM 38 described later by the command register 37. When the power supply is turned on, the return time measurement value is read out from the NVM 38 by the command register 37, held in the command register 37, and updated by the interface section 31 according to the measurement of the return time. Also, instead of measuring the return time, a return time assumption value may be stored in advance in the NVM 38. In a fourth embodiment to be described later, the interface section 31 reads the return time measurement value from the NVM 38 via the command register 37 in response to a request from the host at the time of turning on the power, and sends it to the host.

The checksum circuit 32 is configured to perform an arithmetic operation (checksum) to obtain a checksum value and store the obtained checksum value in the memory 32a each time it receives one screen-ful of RGB data RGBD. Specifically, the checksum circuit 32 obtains a checksum value of a set of RGB data RGBD for a given frame (preceding frame), stores the obtained checksum value in the memory 32a, and then obtain a checksum of a set of RGB data RGBD for the frame that follows immediately after (current frame or subsequent frame). The checksum value of the current frame and the checksum value of the preceding frame stored in the memory 32a are compared to each other. If the two values are equal to each other, it is determined that the two images are identical with each other; if the two values are different from each other, it is determined that the two images are different from each other. The result is a checksum result data CRC, which is then sent to the timing generator 35. The checksum circuit 32 is utilized as described above because it is easy to reliably determine whether or not the RGB data RGBD is updated, and the method does not require a memory of a large capacity. The checksum circuit 32 may also be called “image-change detection circuit”. Alternative arithmetic operations other than checksum may be utilized to determine whether or not the images are identical. In such a case, the checksum circuit 32 is replaced with a different circuit for such an arithmetic operation. Hereinafter, description will assume that the checksum value is a result of checksumming a set of one screen-ful of image data and is a value obtained for each frame. However, a checksum value may be obtained from predetermined lines or a predetermined block for example.

The command register 37 holds command data CM. The command register 37 has three registers 37a through 37c, each storing a value for a different setting from others. An example is a non-refreshing frame count NREF which determines the number of frames for which refreshing is not performed.

The NVM 38 holds setting data SET for various kinds of control. The command register 37 reads the setting data SET which is held in the NVM 38, and also updates the setting data SET in response to command data CM. The command register 37 supplies the timing control signal TS and the setting values stored in the registers 37a through 37c to the timing generator 35, and a voltage setting signal VS to the built-in power supply circuit 39 in response to the command data CM and the setting data SET.

The timing generator 35 receives the checksum result data CRC from the checksum circuit 32. If the checksum result data CRC indicates that the RGB data RGBD is not been changed, the timing generator 35 increments the value of the counter 35a, and then compares said value of the counter 35a with the non-refreshing frame count NREF which is stored in the register 37c. If the value of the counter 35a is smaller than the non-refreshing frame count NREF, refreshing is not performed. As a result, the same image is continuously displayed in the display section 600. On the other hand, if the value of the counter 35a is greater than the non-refreshing frame count NREF, a control signal necessary to perform screen refreshing is supplied to the latch circuit 34 and the counter 35a is reset.

The timing generator 35 generates control signals for controlling the latch circuit 34, the data-side control signal output section 36 and the scanning-side control signal output section 42 based on the vertical synchronization signal VSYNC, the horizontal synchronization signal HSYNC, the data enable signal DE, the clock signal CLK and a built-in clock signal ICK which is generated in the OSC 41, and provides the signals to respective components.

When performing refreshing, there can be a case where the timing generator 35 requests the host 100 to send data DAT. In this case, a request signal REQ is generated based on vertical synchronization signal VSYNC, horizontal synchronization signal HSYNC, data enable signal DE, clock signal CLK, timing control signal TS, and built-in clock signal ICK generated in the OSC 41, and the generated request signal REQ is sent to the host 100. Upon receiving the request signal REQ, the host 100 sends the data DAT to the DSI communication section 31a of the display control circuit 200. It should be noted here that the OSC 41 is not an essential constituent element if the display control circuit 200 has a Video Mode RAM Through configuration.

The latch circuit 34 provides the data-side control signal output section 36 with RGB data RGBD for each line based on a control signal from the timing generator 35. As described above, screen refreshing is performed at a necessary timing, thereby replacing an image which is currently displayed in the display section 600 with the same or a changed image.

The built-in power supply circuit 39 generates and outputs a power voltage, and a common voltage Vcom, for use at the data-side control signal output section 36 and the scanning-side control signal output section 42, based on electric power from the host 100 and a voltage setting signal VS from the command register 37.

The data-side control signal output section 36 generates the data-side control signal SCT based on the RGB data RGBD from the latch circuit 34, the control signal from the timing generator 35, and a power source voltage from the built-in power supply circuit 39; and provides this signal to the data signal line drive circuit 310.

The scanning-side control signal output section 42 generates the scanning-side control signal GCT based on the control signal from the timing generator 35 and the power source voltage from the built-in power supply circuit 39; and provides this signal to the scanning signal line drive circuit 320.

It should be noted here that since the display device 11 is provided by an LCD module, AC driving is utilized to drive the display section 600 to avoid deterioration of the liquid crystal. In other words, polarity (voltage polarity at the pixel electrode 612 with respect to the voltage Vcom at the common electrode 613 as a baseline) of data signal supplied to each pixel formation portion 610 in the display section 600 is inversed for every predetermined period (hereinafter, this predetermined period will be called “inversion cycle”) for a purpose that the voltage applied to the liquid crystal in the display section 600 will have a time average value or an integral value of “zero”. In an intermission driving mode, however, the inversion cycle is significantly longer than in normal driving mode. Because of this, impurity ions distributed unevenly in the liquid crystal of the display section 600 can create a large accumulation of charge (hereinafter simply called “charge imbalance”), and there can be cases where power supply to the display device is turned OFF while the charge imbalance is large. To solve this, there is an arrangement that a total time for which a positive-polarity data voltage was applied to a specific pixel formation portion in the display section 600 and a total time for which a negative-polarity data voltage was applied to the same specific pixel formation portion are monitored; a difference between the two values is held by a predetermined counter; and the value in the counter is updated as the polarity inversion goes on (hereinafter this counter will be called “polarity imbalance counter”). In this case, the value of the polarity imbalance counter is another consideration in determining the refreshing timing of display image.

### 1.5 Video Driver Operation in the Host

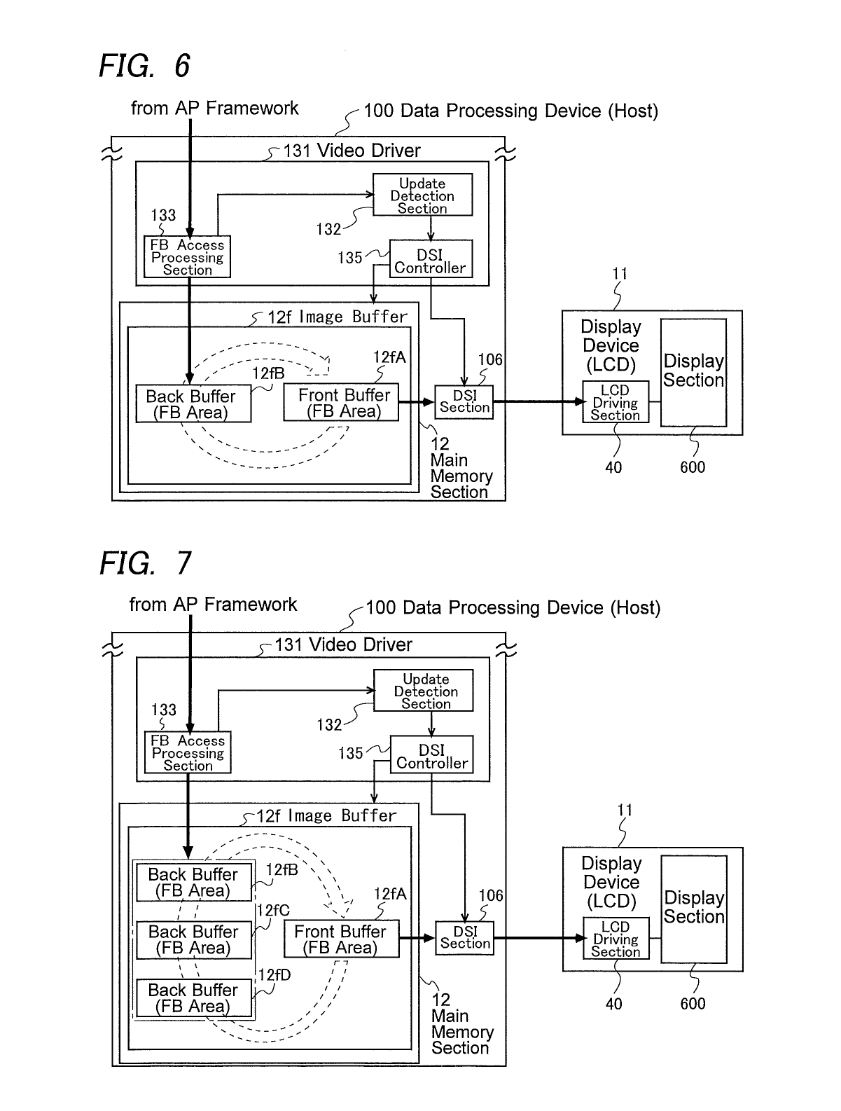

Next, operation of the data processing device (host) 100 for displaying an image in the display device 11 configured as described above will be described with reference to FIG. 2, and FIG. 6 through FIG. 10, with a focus on how the video driver 131 operates. In the following description, the CPU 101 includes several timers for use in its operation; specifically, a period timer for periodic interruption at an interval of one frame period; and a refreshing start timer which sets an amount of time until a start of refreshing as will be described later. As each timer times out when the set amount of time has passed, a corresponding timer interruption takes place.

As has been described, when updating a display image, each application Appi (i=1, 2, 3, . . . ) writes new display image data into the image buffer 12f (display image data updating) by using the FB access processing section 133 via the surface flinger 121 in the AP frame work 120 (see FIG. 2). In this procedure, the FB access processing section 133 notifies the update detection section 132 of an access event which indicates a data updating event in the image buffer 12f. The notification takes a form of a function provided by the OS 130 for synchronization (e.g. system function such as a “signal”).

The image buffer 12f is implemented as a memory area allocated in the memory section 12, and its size changes in accordance with extension of its memory area and release of the extension as described later. The image buffer 12f can be extended in units of a memory area (hereinafter referred to as “frame buffer area” or “FB area”) for storing display image data for one frame. Hereinafter, a configuration and operation of the image buffer 12f will be described with reference to FIGS. 6 and 7. FIG. 6 is a block diagram for describing writing and reading of the display image data in the unextended image buffer 12f in the present embodiment, and FIG. 7 is a block diagram for describing writing and reading of the display image data into and from the image buffer 12f under an extension state.

As shown in FIG. 6, the unextended image buffer 12f is composed of two FB areas 12fA and 12fB. One of these FB areas 12fA and 12fB serves as a front buffer that can be read by the DSI section 106 and the other serves as a back buffer for storing new display image data when reading of the display image data stored in the front buffer is not completed. FIG. 6 shows an operation state in which the FB area 12fA serves as a front buffer and the FB area 12fB serves as a back buffer. In the operation state shown in FIG. 6, when reading of the display image data from the FB area 12fA as a front buffer is completed and writing of new display image data into the FB area 12fB as a back buffer is completed, the front buffer and the back buffer are exchanged with each other. That is, the FB area 12fB serves as a front buffer, and the FB area 12fA serves as a back buffer. Thus, every time reading from the front buffer and writing into the back buffer are completed, the front buffer and the back buffer are exchanged with each other.

As shown in FIG. 6, in the unextended image buffer 12f, when the writing of the display image data into the FB area 12fB as a back buffer is completed and new display image data is supplied from the FB access processing section 133 (when new image data is updated), before the reading of the display image data from the FB area 12fA as a front buffer is completed, the new display image data will be lost (hereinafter this missing will be referred to as “frame missing”). Therefore, as shown in FIG. 7, in the present embodiment, the image buffer 12f can be extended so as to avoid such missing (frame missing) of display image data. In other words, in the present embodiment, as necessary, in addition to the FB areas 12fA and 12fB for two frames in the unextended image buffer 12f, two further FB areas 12fC and 12fD are provided as the image buffer 12f in the extension state and are allocated in the memory section 12. In the example shown in FIG. 7, an extension portion in the image buffer 12f is FB areas for two frames, but it is not limited thereto, and it may be FB areas for three frames or more (The appropriate number of extension frames in the image buffer 12f will be described later). Also, in the present embodiment, the unextended image buffer 12f is composed of two FB regions 12fA and 12fB, but it is not limited thereto, and it may have at least one FB region.

Of the four FB areas 12fA, 12fB, 12fC, and 12fD constituting the image buffer 12f in the extension state in the present embodiment, one FB area serves as a front buffer, the other three FB areas serve as back buffers, and the three back buffers are ranked (hereinafter referred to as “first back buffer”, “second back buffer”, “third back buffer” in descending order of higher back buffers). When new display image data is supplied to the image buffer 12f in a state in which reading of the display image data from the front buffer is incomplete, the new display image data is written into the first back buffer. When new image data is further supplied to the image buffer 12f, this new display image data is written into the second back buffer. In this way, when sets of new display image data are sequentially supplied to the image buffer 12f in a state in which reading of the display image data in the front buffer is not completed, the sets of new display image data are sequentially written into the back buffers in order from the one with the highest ranking.

FIG. 7 shows an operation state in which the FB area 12fA serves as a front buffer, and the FB areas 12fB, 12fC, and 12fD serve as first, second, and third back buffers, respectively. In the operation state shown in FIG. 7, when reading of the display image data from the FB area 12fA as the front buffer is completed and writing of new display image data to the FB area 12fB as the first back buffer is completed, the front buffer and the first to third back buffers cyclically interchange. That is, the FB area 12fA as the front buffer changes so as to serve as the third back buffer, the FB area 12fB as the first back buffer changes so as to serve as the front buffer, the FB area 12fC as the second back buffer changes so as to serve as the first back buffer, and the FB area 12fD as the third back buffer changes so as to serve as the second back buffer. In this manner, the writing of the display image data into the image buffer 12f and the reading from the image buffer 12f are performed by the first-in first-out method. However, when the display image data is to be transferred to the display device 11 before new display image data is transferred to the image buffer 12f after reading of the display image data in the front buffer is completed, the display image data in the front buffer is read out again. This also applies to the unextended image buffer as shown in FIG. 6.

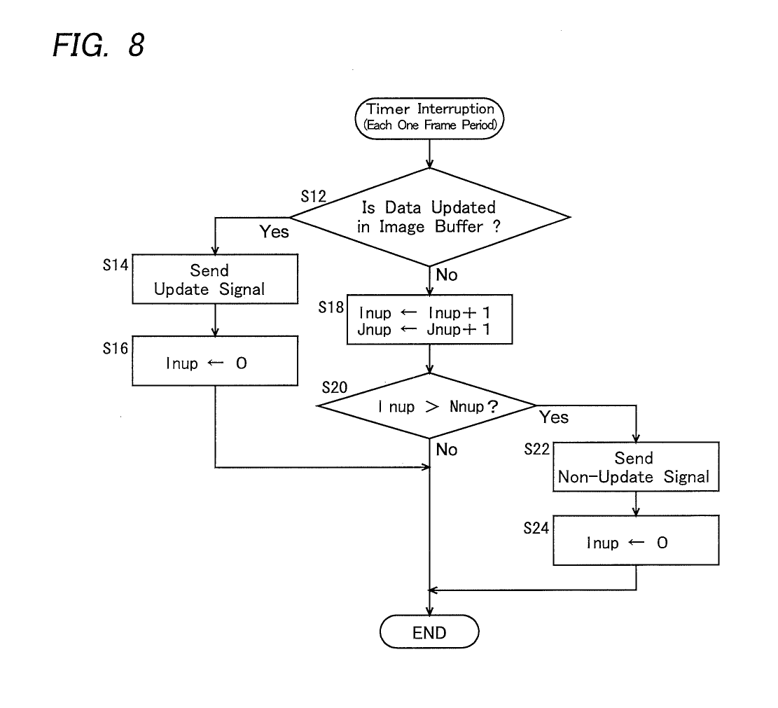

The update detection section 132 is implemented as a timer interrupt handler which is activated by the timer interruption generated by the above-described period timer at intervals of one frame period (16.67 ms in the present embodiment). FIG. 8 is a flow chart which shows a processing procedure by the timer interrupt handler. Upon the timer interruption, the CPU 101 operates as follows:

First, presence or absence of the above-described access event notification is checked to determine if display image data in the image buffer 12f is updated, that is, if new display image data is written into a back buffer in the image buffer 12f (Step S12). For this determination, a function of the OS 130 (e.g. a system function such as “wait”) for receiving the access event is utilized.

If the result of determination in Step S12 indicates that the display image data in the image buffer 12f is updated, the CPU proceeds to Step S14 and sends a signal to notify the update of the display image data (hereinafter called “update signal”), to the DSI controller 135 (Step S14). Thereafter, a variable which indicates a length of the periods during which the display image data has not been updated (hereinafter called “first non-update variable”) Inup is reset to “0” (Step S16), and then this timer interrupt handler is terminated.

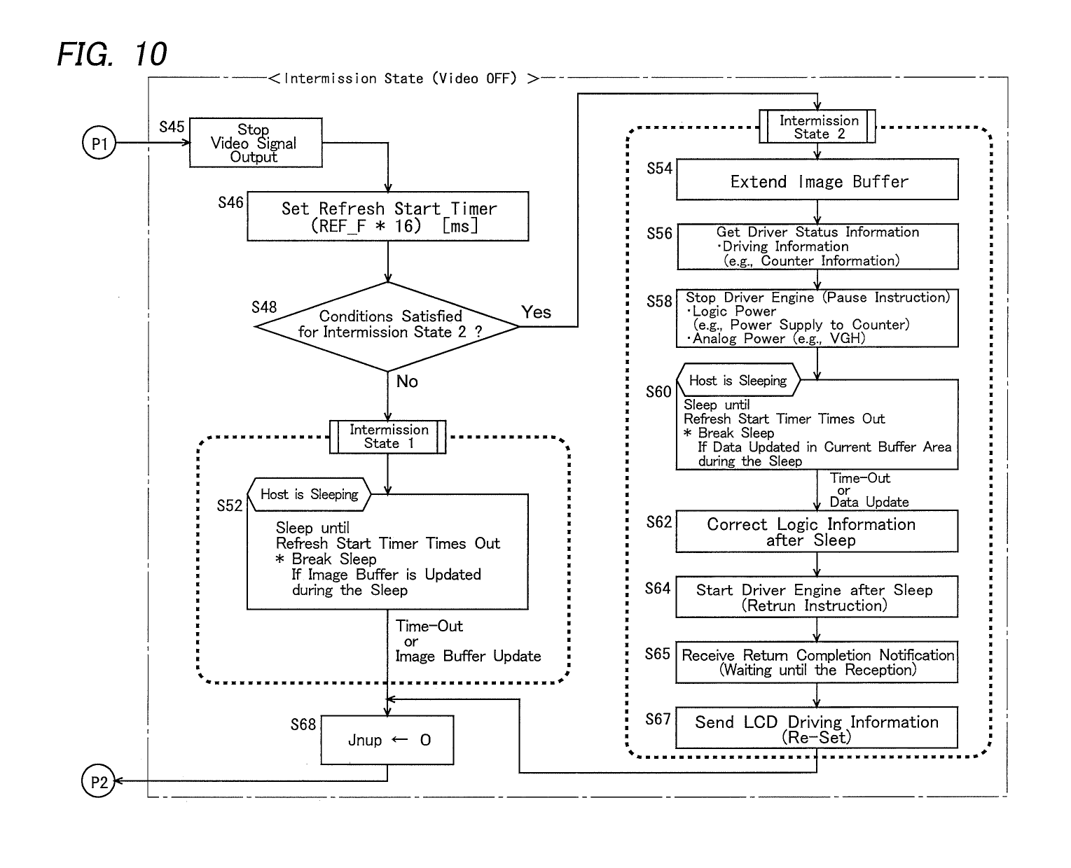

If the result of determination in Step S12 does not indicate an update of the display image data in the image buffer 12f, the CPU proceeds to Step S18 and increases the value of the first non-update variable Inup by “1” (Step S18), and thereafter, checks whether or not the first non-update variable Inup is greater than a predetermined criterion value Nnup (“2” for example) (Step S20). If the result of determination shows that the first non-update variable Inup is not greater than the criterion value Nnup, this timer interrupt handler is terminated. If the result of determination shows that the first non-update variable Inup is greater than the criterion value Nnup, a signal which indicates that updating of the display image data in the image buffer 12f has not been performed for a predetermined time (hereinafter called “non-update signal”) is sent to the DSI controller 135 (Step S22). However, sending of the non-update signal is not executed or is ignored if the DSI controller 135 is in an intermission state (Intermission State 1 or 2, with Video OFF) (in other words, from an execution time point of Step S45, through steps shown in FIG. 10, to Step S35) which will be described later.

Once the non-update signal is sent, the first non-update variable Inup is reset to “0” (Step S24), and this timer interrupt handler is terminated. The criterion value Nnup is a value selected for a judgment that the display image should be regarded as a still image if the first non-update variable Inup is greater than the criterion value Nnup. Therefore, the criterion value Nnup is not limited to “2”; rather, any appropriate value greater than “1” may be selected as a criterion to see whether an image to be displayed is a changed image. The first non-update variable Inup is initialized to “0” when the data processing device 100 is started.

This timer interrupt handler is started every frame period as has been described, but once started, it is terminated within a much shorter period than one frame period as will be understood from FIG. 8.

Next, operation of the DSI controller 135 in the video driver 131 will be described. In the DSI video mode, display image data is transferred from the host, i.e., the data processing device 100, to the display device 11 for each frame period. In the present embodiment, however, in order to reduce power consumed by the host in the intermission driving mode, the DSI controller 135 has two operation states, i.e., Normal State (Video ON) in which display image data is transferred to the display device 11 for each frame period, and Intermission State (Vide OFF) in which transfer of display image data to the display device 11 is stopped when there is no need for updating the display image in the display device 11. The DSI controller 135 is implemented as a process (including threads) which operates as part of the OS 130 in the kernel space, or in other words implemented as a system process, and this system process enters a sleep state in the above-described Intermission State, under a process management by the OS 130 (a system function such as “sleep” is utilized for this).

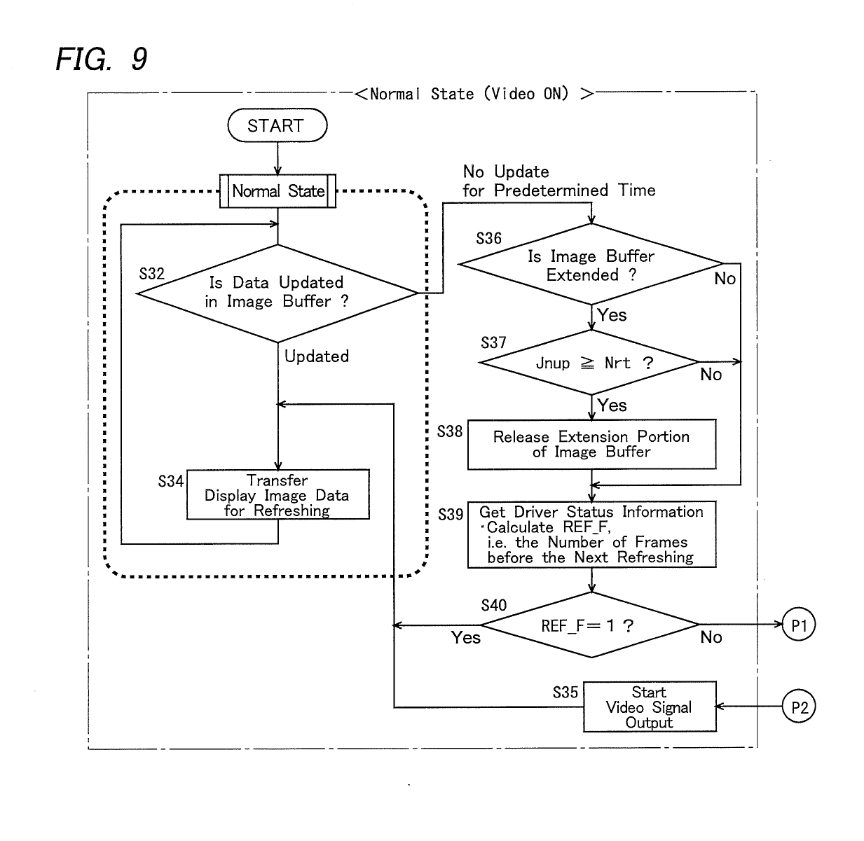

FIG. 9 is a flow chart which shows a processing procedure of the DSI controller 135 in Normal State; FIG. 10 is a flow chart which shows a processing procedure of the DSI controller 135 for shifting from Normal State to Intermission State 1 or 2, and a processing procedure of the DSI controller 135 for returning to Normal State from Intermission State 1 or 2 (Hereinafter, simply called “processing procedure of the DSI controller for Intermission State”). When the data processing device 100 serving as the host is started, the CPU 101 operates as shown in FIGS. 9 and 10, thereby implementing the DSI controller 135 as a process in the kernel space.

Specifically, when the data processing device 100 is started, the CPU 101 determines whether or not display image data in the image buffer 12f is updated (Step S32). The determination in Step S32, that is, whether or not display image data in the image buffer 12f is updated is made by receiving an update signal or a non-update signal from the timer interrupt handler (see Steps S14 and S22 in FIG. 8) (system function such as “wait” is utilized for receiving a signal like this). If in Step S32 an update signal is determined to be received, the CPU proceeds to Step S34, following the recognition that there was an update of the display image data in the image buffer 12f. In Step S34, the DSI section 106 is caused to transfer the post-update display image data which is stored in the image buffer 12f (the display image data in a front buffer which will be described later) to the display device 11. Thereafter, the CPU returns to Step S32. The display device 11 which receives the display image data performs the steps as has been described earlier, to display an image that is represented by this display image data in the display section 600, whereby refreshing of the display image is achieved (see FIGS. 3 and 5). The transfer of the display image data by the host in Step S34, the reception of the display image data by the LCD, and the refresh of the display image are set so that the timing and the speed coincide with each other based on the video mode of the MIPI-DSI standard. In the present embodiment, the transfer and refresh are performed at 60 [frames/sec] so as to correspond to the cycle of the timer interruption in FIG. 8.

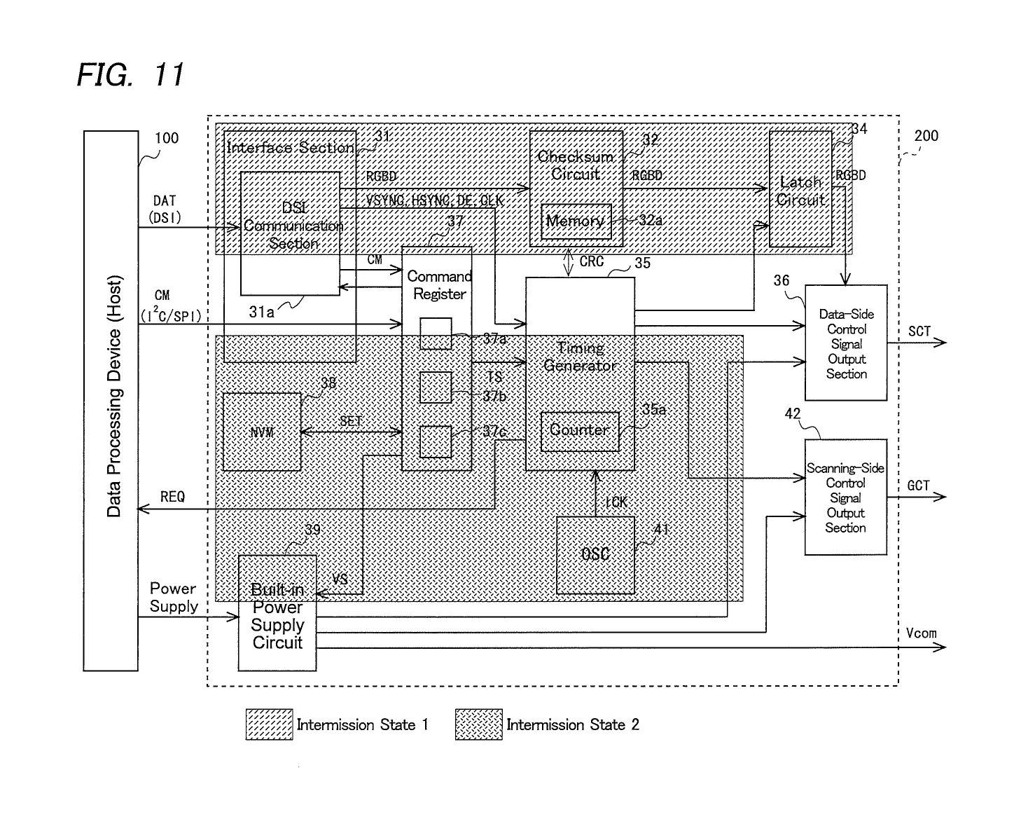

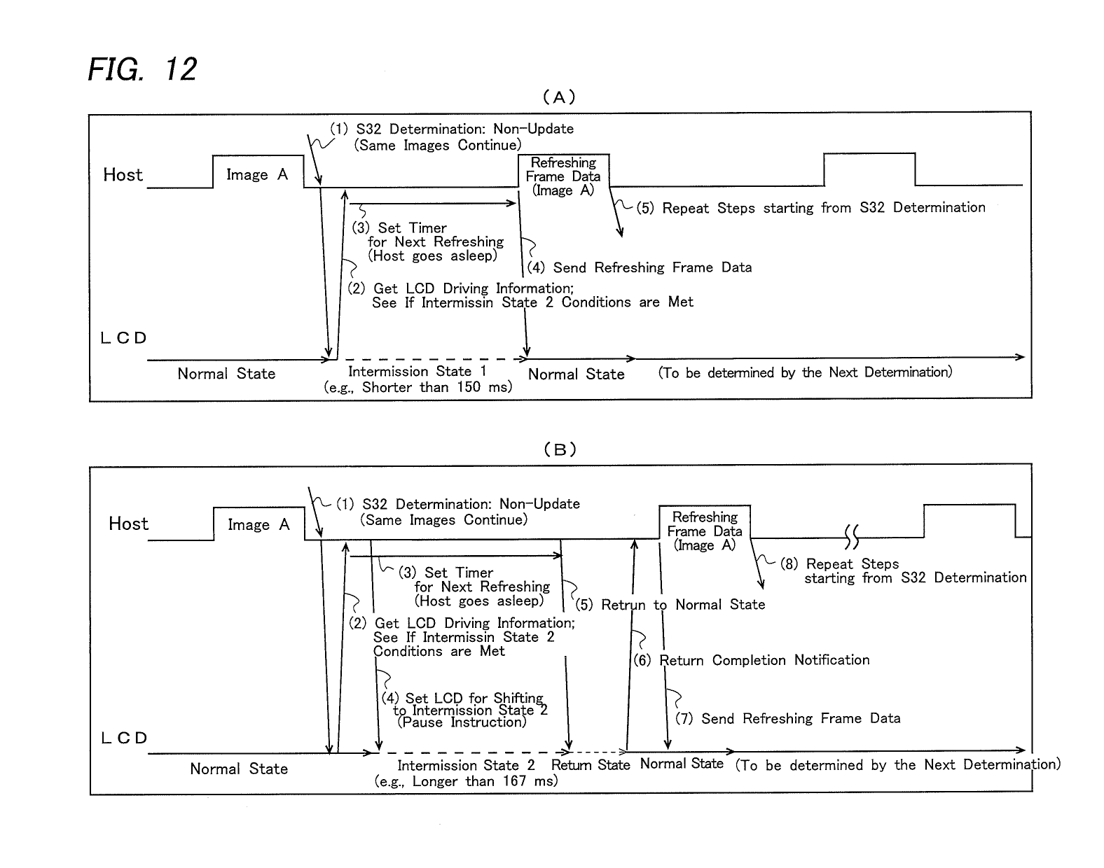

The image buffer 12f can store display image data for a plurality of frames (see FIGS. 6 and 11 described later). Before an update signal generated by writing the display image data of one frame into the image buffer 12f is received in Step S32, an update signal may be newly generated by writing display image data of the next frame into the image buffer 12f. In this way, there may be a plurality of unreceived update signals (pending update signals), in which case Steps S32 and S34 are repeated until there are no unreceived update signals. If neither an update signal nor a no-update signal exists, the process waits in Step S32 until it receives any of these signals, but the DSI section 106 is still in operation during the waiting period, and therefore the display image data stored in the front buffer is transferred to the LCD every frame period.

If a non-update signal is determined to be received in Step S32, it means that display the image data in the image buffer 12f is not updated for a predetermined amount of time. In this case, the process proceeds to Step S36 to determine whether or not the image buffer 12f is extended. As a result of this determination, if the image buffer 12f is not extended, the process proceeds to Step S39. On the other hand, if the image buffer 12f is extended, it is determined whether the second no-update variable Jnup is greater than or equal to a preset number (hereinafter referred to as “the number of return time frames)” Nrt, which is the number of frame periods corresponding to the return time (Step S37). As a result of this determination, if the second no-update variable Jnup is smaller than the number of return time frames Nrt, the process proceeds to Step S39. If the second no-update variable Jnup is greater than or equal to the number of return time frames Nrt, the extension portion of the image buffer 12f is released (Step S38), and then the process proceeds to Step S39. However, if there is a possibility that one of the display image data stored in the FB areas 12fC and 12fD as the extension portion is possibly read out, the image buffer 12f remains in the extension state without releasing the extension portion, and releases it when all the unread display image data in the extension portion has been read out. That is, at the time point when all the display image data stored in the FB areas 12fC, 12fD as the extension portion has been transferred to the LCD and neither of the FB areas 12fC, 12fD serves as a front buffer, the FB areas 12fC, 12fD are released. Here, in the case of releasing the extension portion of the image buffer 12f, memory management function provided by the OS 130 is used. As a result, in the present embodiment, among the four FB regions 12fA to 12fD constituting the image buffer 12f in the extension state (see FIG. 7), the two FB regions 12fC and 12fD as the extension portions are released and one of the two other FB areas 12fA and 12fB serves as a front buffer and the other serves as a back buffer (see FIG. 6).

In Step S39, there is obtained driver status information, i.e., information regarding driving state at the display device 11 (hereinafter called “LCD driving information”). This LCD driving information contains a count of the frames in the non-refreshing period (value in the counter 35a); a value which indicates a difference between a total time for which a positive-polarity data voltage was applied to a specific pixel formation portion in the display section 600 and a total time for which a negative-polarity data voltage was applied to the same specific pixel formation portion (value in the polarity imbalance counter); etc., and therefore can be understood as information regarding determination on refreshing timing of display image in the display device 11 (hereinafter called “refreshing-related information”). In the present embodiment, at least a value in the counter 35a (hereinafter called “non-refreshing count”) in the display control circuit 200 (FIG. 5) is obtained as the LCD driving information. Also, in cases where the earlier-described polarity imbalance counter is provided in the display control circuit 200, a value of the polarity imbalance counter (hereinafter called “polarity imbalance count”) is also obtained as part of the LCD driving information.

The above-described LCD driving information from the display device 11 is obtained by using commands conforming to MIPI-DSI Standards, via an interface conforming to MIPI-DSI Standards. Alternatively, the information from the display device 11 may be obtained via an interface which conforms to I2C Standards or SPI Standards (see FIG. 5). Such an arrangement will be described later as a second embodiment. In Step S39, the LCD driving information, which includes information from counters such as non-refreshing count, is obtained from the display device 11 as described, and then based on the obtained LCD driving information, a calculation is made for the number of frames preceding the next refreshing of the display image (hereinafter called “refreshing start preceding frame count”) REF_F. This refreshing start preceding frame count REF_F corresponds to an intermission period (non-refresh period) in the intermission drive mode of the display device 11.

Next, the CPU determines whether or not this refreshing start preceding frame count REF_F is “1” (Step S40). If the result of determination indicates that the refreshing start preceding frame count REF_F is “1”, the CPU proceeds to Step S34 to cause the DSI section 106 to transfer display image data stored in the image buffer 12f to the display device 11. Thereafter, the CPU returns to Step S32. The display device 11 refreshes the display image using this display image data. On the other hand, if the result of determination indicates that the refreshing start preceding frame count REF_F is not “1”, i.e., is “2” or a greater number, the CPU proceeds to Step S45 in FIG. 10 in order to bring the DSI controller 135 into the intermission state.

Moving to Step S45 in FIG. 10 means that the display device 11 is operating in the intermission driving mode and displaying a still image. Based on this, the DSI section 106 is caused to stop transferring display image data to the display device 11. In other words, video signal output from the data processing device 100 to the display device 11 is stopped. Thereafter, a setting is made to the earlier-described refreshing start timer (Step S46) for a timeout after a length of time equal to the refreshing start preceding frame count REF_F from the current time point. Since one frame period is 16.67 ms in the present embodiment, the length of time set to the refreshing start timer is (REF_F*16) ms. Thereafter, the CPU proceeds to Step S48.

In the present embodiment, the intermission state of the DSI controller 135 consists of two levels, i.e., Intermission State 1 and Intermission State 2. Depending on a driving state of the display device 11 at a time point when a determination is made to shift from Normal State to Intermission State, selection is made as to which of the Intermission State 1 and Intermission State 2 the shifting should be made to. Intermission State 2 is selected if it is possible to stop a greater number of circuits in the display device 11 or to turn off a greater number of power supplies for greater power saving than in Intermission State 1. In Step S48 CPU 101 determines which of Intermission State 1 and Intermission State 2 should be selected. In the present embodiment, Intermission State 1 is selected if the refreshing start preceding frame count REF_F calculated in Step S39 is not greater than “10”, whereas Intermission State 2 is selected if the number is greater than “10”. The Intermission State 1 can be considered as “short intermission state” because the time to start of the next refresh in the Intermission State 1 is shorter than in the Intermission State 2. It should be noted here that the selection criteria is not limited to whether or not the refreshing start preceding frame count REF_F is not greater than “10”, but selection may be made by taking characteristics, operating conditions, etc. of the display device 11 into consideration.

If the result of determination in Step S48 shows that the refreshing start preceding frame count REF_F is not greater than 10, shifting should be made to Intermission State 1, so the CPU proceeds to Step S52. In Step S52, the host (DSI controller 135 therein) assumes a sleep state. Specifically, under the process management by the OS 130, the CPU 101 executes system functions for bringing the process which is working as the DSI controller 135 into the sleep state. The process which assumes the sleep state, i.e., the process which is now stopped, is resumed (brought back to an active state) when the refreshing start timer times out as the earlier-mentioned length of time (REF_F*16) ms has elapsed. However, even before the elapse of the time (REF_F*16) ms, the process management is configured to resume the process if it receives an update signal (Step S14 in FIG. 8) based on an update of display image data in the image buffer 12f. Following the steps described above, the DSI controller 135 in the sleep state returns to Normal State as the CPU moves from Step S52 to the next Step S35 (FIG. 9) via Step 68 in which the second no-update variable Jnup is reset to “0”, when the refreshing start timer times out or display image data in the image buffer 12f is updated.

Step S35 causes the DSI section 106 to resume its operation for transferring display image data to the display device 11. In other words, video signal output from the data processing device 100 to the display device 11 is started. Thereafter, the CPU proceeds to Step S34 to cause the DSI section 106 to transfer display image data in the image buffer 12f to the display device 11 (to be exact, the display image data in the front buffer described later), and then the CPU returns to Step S32. It should be noted here that the DSI communication section 31a in the display control circuit 200 is configured to resume its operation if it receives a video signal (specifically, the vertical synchronization signal VSYNC) from the host in the intermission state (power saving state).

If the result of determination in Step S48 indicates the condition for shifting to Intermission State 2 is satisfied (if the refreshing start preceding frame count REF_R is greater than 10 in the present embodiment), the CPU proceeds to Step S54 and extends the image buffer 12f by FB areas of two frames (FIG. 6→FIG. 7). For extension of the image buffer 12f, the memory management function by the OS 130 is used. As a result, the image buffer 12f is composed of the FB areas 12fA and 12fB as the unextended image buffer 12f and the FB areas 12fC and 12fD as the extension portion (see FIG. 7).

Thereafter, LCD driving information is obtained as driver status information from the display device 11 (Step S56) by using commands based on MIPI-DSI Standards. The LCD driving information contains not only counter information such as the non-refreshing count, but also information for resuming various circuits (specific circuits called “driver engine”) within the display control circuit 200 which is to be stopped in the next Step S58 (see Step S67).

After the LCD driving information is obtained, predetermined various circuits in the display control circuit 200 of the display device 11 are stopped by using commands based on MIPI-DSI Standards, etc., and instructions for turning OFF logic power sources and analog power sources used by these circuits, namely, a pause instruction is sent to the display device 11 (Step S58). Circuits which are stopped in the display control circuit 200 in Intermission State 1 (hereinafter referred to as “first circuits”) are those each having a relatively short time required for resuming operation from the stopped state (this required time is equal to or shorter than a predetermined time), the first circuits being hatched with slanted dot lines drawn in one direction in FIG. 11. In Intermission State 2, other circuits hatched with slanted dot lines drawn in two directions in FIG. 11 (hereinafter referred to as “second circuits”) are also stopped. It should be noted here that the first circuits which are stopped in Intermission State 1 are configured to automatically stop (assume a power-save state) upon stopping video signal output from the host (Step S45). The second circuits which are stopped only in Intermission State 2 are configured to stop upon issuance of commands from the host (Step S58). In the present embodiment, the data-side control signal output section 36 and the scanning-side control signal output section 42 do not stop in any of Intermission State 1 and 2; however, they may be configured to come into stoppage in Intermission State 1, for example.

Thereafter, the DSI controller 135 assumes a sleep state (Step S60). Specifically, under the process management by the OS 130, the CPU 101 executes system function for bringing the process which is working as the DSI controller 135 into the sleep state. The process which is in the sleep state and therefore is a non-operating process resumes its operation once the time (RER_F*16) ms which was set in Step S46 has elapsed and the refreshing start timer times out. It should be noted here that, the process management by the OS 130 is configured such that even when the above time (REF_F*16) ms has not elapsed yet, the process is restarted upon receiving the update signal (Step S14 in FIG. 8) based on the data update in the image buffer 12f. In this manner, when the refreshing start timer times out or the display image data in the image buffer 12f is updated, the DSI controller 135 in the sleep state proceeds from Step S60 to next Step S62.

In Step S62, corrections are performed to logic information related to those circuits in the display control circuit 200 which were stopped in Intermission State 2. In the present embodiment, corrections are made to the non-refreshing count and the polarity imbalance count which were obtained in Step S56, based on the refreshing start preceding frame count REF_F (length of the period of Intermission State) so as to compensate for the circuit stoppage.

Next, power supply is resumed to each of the circuits which were stopped in the display control circuit 200, and instructions for starting these stopped circuits are sent as a return instruction to the display device 11 (Step S64) using commands based on MIPI-DSI Standards. Thereafter, the process waits until it receives a return completion notification from the display device 11 (step S65), and upon receiving the return completion notification, it proceeds to Step S67.

In Step S67, using commands which are based on MIPI-DSI Standards, LCD driving information which contains logic information after the correction is sent to the display device 11 so that this LCD driving information is re-set in the display control circuit 200 of the display device 11.

After transmitting the LCD drive information to the display device 11, the process proceeds to Step S35 of resetting the second no-update variable Jnup to “0”, and then proceeds to Step S35 corresponding to Normal State, in which the CPU causes the DSI section 106 to resume its operation for transferring display image data to the display device 11 (Start video signal output). Thereafter, the process proceeds to Step S34 to cause the DSI section 106 to transfer display image data stored in the image buffer 12f to the display device 11, and then the CPU returns to Step S32.

### 1.6 Basic Operation

Next, a basic operation of the above-described present embodiment will be described with reference to FIG. 12 together with FIGS. 9 and 10. Hereinafter, description will focus, among other operations performed in the data processing device 100 as the host, on data exchange with the display device 11, with an understanding that the operation state (“Normal State”, “Intermission State 1”, or “Intermission State 2”) of the DSI controller 135 described above is the state of the CPU 101 or the host, and also the state of the display device 11 (referred to as “LCD” in FIG. 12 and thereafter). Further, in relation to the arrangement that the DSI controller 135 in the host assumes a sleep state in Intermission State 1 and Intermission State 2 (Steps S52 and S60), the state of DSI controller 135, sleep or awake, will be regarded as the state of the host, sleep or awake, where convenient in the following description since the present invention is uniquely characterized by control of a display device.

(A) of FIG. 12 is a sequence diagram for describing operation when the host shifts to Intermission State 1 in the present embodiment. With reference to (A) of FIG. 12, when there is a determination, in Normal State, that a transfer of data which represents Image A from the host to the LCD has not been followed by any data update in the image buffer 12f for a predetermined amount of time (Step S32; (1) in (A) of FIG. 12), the host obtains LCD driving information from the LCD, and calculates the refreshing start preceding frame count REF_F based on a non-refreshing count contained in the LCD driving information (Step S39).

If the refreshing start preceding frame count REF_F is greater than “1”, video signal output from the DSI section 106 is stopped (Step S40 and S45), and a determination is made based on this refreshing start preceding frame count REF_F as to whether or not conditions for shifting to Intermission State 2 are met (Step S48; (2) in (A) of FIG. 12). In the current example, the time for starting the next refreshing is not longer than 150 ms (the refreshing start preceding frame count REF_F is not greater than 10); therefore, the refreshing start timer is set so as to time out upon elapse of a time equivalent to the refreshing start preceding frame count REF_F and thereafter, the host and the LCD shift from Normal State to Intermission State 1 (Step S52; (3) in (A) of FIG. 12).

Thereafter, when the refreshing start timer times out, video signal output by the DSI section 106 is resumed (Step S35), and in order to refresh the display image in the LCD, refreshing frame data (data representing the display image A) is transferred from the host to the LCD (Step S34; (4) in (A) of FIG. 12). Thereafter, the CPU returns to Step S32, to repeat the routine of steps thereafter ((5) in (A) of FIG. 12).

As described above, if the LCD displays the Image A as a still image (if the image to be displayed is not changed), and the refreshing start preceding frame count REF_F which is calculated from LCD driving information obtained from the LCD is not greater than “10”, the data representing the Image A is transferred as refreshing frame data to the LCD for each length of time equal to the refreshing start preceding frame count REF_F; and in those periods in which the transfer is not made, the DSI controller 135 in the video driver 131 of the host assumes a sleep state, namely, the host and the LCD assume Intermission State 1.

(B) of FIG. 12 is a sequence diagram for describing operation when the host shifts to Intermission State 2 in the present embodiment. As shown in (B) of FIG. 12, after the host transfers data which represents an Image A to the LCD in Normal State, similar steps as in (A) of FIG. 12 are followed to stop video signal output from the DSI section 106 (Steps S32, S39, S40, S45; (1) in (B) of FIG. 12); the above-mentioned refresh start timer is set so as to time out when the time (REF_F*16) ms corresponding to the refreshing start preceding frame count REF_F has elapsed from the present time (step S46). Here, the refreshing start preceding frame count REF_F is calculated based on the LCD drive information obtained from the LCD (see Step S39). In next Step S48, based on the refreshing start preceding frame count REF_F, a determination is made as to whether or not conditions for shifting to Intermission State 2 are met (Step S48; (2) in (B) of FIG. 12).

In this example shown in (B) of FIG. 12, the time before starting the next refreshing is not shorter than 167 ms (the refreshing start preceding frame count REF_F is greater than “10”); therefore, with the refreshing start timer being set so as to time out upon elapse of a time equivalent to the refreshing start preceding frame count REF_F (Step S46; (3) in (B) of FIG. 12), the host and the LCD shift from Normal State to Intermission State 2 (Steps S54 through S60). In the above, first, the image buffer 12f is extended by FB areas 12fC and 12fD for two frames (Step S54). Thereafter, instructions are sent to the LCD for bringing the LCD into Intermission State 2 by stopping predetermined circuits in the LCD and turning off predetermined power sources (Step S58; (4) in (B) of FIG. 12).

Thereafter, when the refreshing start timer times out, information necessary for the next refreshing of the display image in the LCD, i.e., information and instructions for bringing the LCD back into Normal State, are sent to the LCD and the host waits until it receives a return completion from the LCD (Steps S62 through S65; (5) and (6) in (B) of FIG. 12).

Upon receiving the return completion notification from the display device 11 ((6) in (B) of FIG. 12), after the LCD driving information is sent to the LCD for resetting (Step S67), the video signal output by the DSI section 106 is resumed (Step S35), and in order to refresh the display image in the LCD, refreshing frame data (data representing the display image A) is transferred from the host to the LCD (Step S34; (7) in (B) of FIG. 12). Thereafter, the process returns to Step S32, to repeat the routine of the steps thereafter ((8) in (B) of FIG. 12).

As has been described above, if the LCD displays the Image A as a still image and if the refreshing start preceding frame count REF_F calculated from LCD driving information obtained from the LCD is greater than “10”, the LCD is brought into Intermission State 2 and the predetermined circuits in the LCD are stopped or their power supply is turned off until the next refreshing of the display image in the LCD, for further reduction in power consumption in the LCD (see FIG. 11). In this case, however, a preparation period is necessary for the next refreshing of display image in the LCD, so recovery from Intermission State 2 to Normal State before starting the next refreshing takes a state under a return (hereinafter referred to as “returning state” or “return state”) in between (see (B) of FIG. 12).

### 1.7 Operation for Preventing Frame Missing

In the basic operation shown in FIG. 12 (B), the refreshing start timer times out at the time according to the refreshing start preceding frame count REF_F, so that the CPU returns from the Intermission State 2 to Normal State through the returning state. In addition to returning to such Normal State, there is a case where a data update (writing of new display image data) is performed in the image buffer 12f due to a user operation on the host side input operation section 16 (for example, a touch panel) before the refreshing start timer times out, so that the CPU returns from Intermission State 2 to Normal State through the returning state. In this case, multiple sets of new display image data are often supplied to the image buffer 12f in succession in the returning state. In the present embodiment, in order to prevent frame missing even when multiple sets of new display image data are successively supplied to the image buffer 12f in the returning state, the image buffer 12f is extended (Step S54) when shifting from Normal State to Intermission State 2. Hereinafter, the operation of the present embodiment will be described from the viewpoint of preventing frame missing by extending the image buffer 12f.

### 1.7.1 Operation in Configuration without Extending Image Buffer

First, for comparison, assuming a configuration in which the image buffer 12f is not extended (hereinafter referred to as “image buffer non-extended configuration”), there will be made a description of operation of returning from Intermission State 2 to Normal State through the returning state due to a data update in the image buffer 12f caused by a user operation on the input operation section 16 in the image buffer non-extended configuration, before a description of the above operation in the present embodiment.

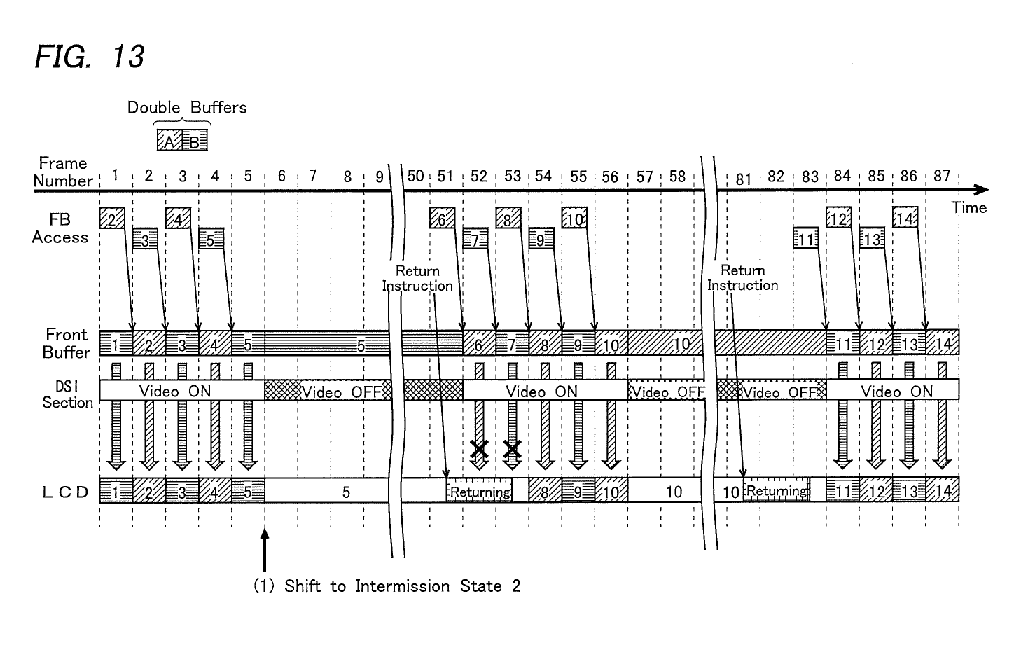

FIG. 13 is a timing chart for describing operation when returning from Intermission State 2 to Normal State through the returning state due to a data update in the image buffer 12f caused by a user operation on the input operation section 16, in the case where the data processing device (host) 100 to which the display device 11 (LCD) is connected has an image buffer non-extended configuration. In this configuration, the image buffer 12f always consists of two FB regions 12fA and 12fB (image buffers having such a configuration are referred to as “double buffers”), one of them serves as a front buffer, and the other serves as a back buffer. In FIG. 13, the FB area 12fA is identified by the symbol “A”, the FB area 12fB is identified by the symbol “B”, the graphic (rectangle) indicating the FB area 12fA is hatched with slanted lines, and the graphic indicating the FB area 12fB is hatched with horizontal lines (the same applies to the other drawings). In each frame period, numerals are assigned to corresponding graphics (rectangles) in the figure in order to identify sets of display image data stored in each FB area, the front buffer, and the LCD (the same also applies in the other figures). These numerals of the sets of the display image data are in ascending order such as 1, 2, 3, . . . , in accordance with the order of being supplied to the image buffer 12f. The sets of display image data identified by the numerals 1, 2, 3, . . . are referred to as “display image data D1”, “display image data D2”, “display image data D3”, . . . in the following description. In FIG. 13, a period during which the DSI section 106 can perform the operation of transferring the data DAT (including display image data) to the LCD, that is, a period during which the video signal is being output from the DSI section 106 is indicated by “Video ON”, a period during which the operation is stopped, that is, a period during which the video signal output from the DSI section 106 is stopped is indicated by “Video OFF” (see also Steps S35 and S45) (the same applies to other drawings).

In the example shown in FIG. 13, in the first frame period, the host and the LCD are in Normal State, display image data D1 is stored in the FB area 12fB as the front buffer in the host, display image data D2 is read into the FB area 12fA as the back buffer, and the display image data D1 in the front buffer is transferred to the LCD and display image of the LCD is refreshed by the display image data D1. In the second frame period, the front buffer and the back buffer are exchanged with each other, the display image data D2 stored in the FB area 12fA as the front buffer is read out and transferred to the LCD, and the display image of the LCD is refreshed by the display image data D2. On the other hand, into the FB area 12fB as the back buffer, display image data D3 newly supplied to the image buffer 12f is written. From then on, display image data D3, D4, and D5 sequentially supplied to the image buffer 12f are transferred to the LCD and used for refreshing the display image of the LCD while the front buffer and the back buffer are being exchanged with each other every frame period.

From the fifth frame period to the 50th frame period, no new display image data is supplied to the image buffer 12f. Therefore, after the display image data D5 in the FB area 12fA serving as the front buffer in the fifth frame period is transferred to the LCD and the display image is refreshed in the LCD, transfer of the display image data to the LCD stops and the display image on the LCD is not refreshed until the 50th frame period. In this example, the host and the LCD shift to Intermission State 2 at the sixth frame period (Steps S36 through S48 and S54 through S60), and the host and LCD are in Intermission State 2 until the 50th frame period.

In the 51st frame period, new display image data D6 is supplied to the image buffer 12f due to a user operation on the input operation section 16 and written into the FB area 12fA as the back buffer, which is detected as a data update in the image buffer 12f, and a return instruction is transmitted from the host to the LCD (Step S64). In the 52nd frame period, the FB area 12fA in which the display image data D6 is stored becomes the front buffer, display image data D7 newly supplied to the image buffer 12f is written into the FB area 12fB as the back buffer while the display image data D6 is read from the FB area 12fA and transferred to the LCD. However, in the LCD, all the circuits can not resume their operations immediately and at this point it is in the returning state. As a result, the display image data D6 is missing during this transfer (occurrence of frame missing). In the image buffer non-extended configuration, since the image buffer 12f is full at this point, Step S65 of receiving the return completion notification is not executed.

As shown in FIG. 13, in this example, the returning state continues since the transfer of the return instruction in the 51st frame period until the middle of the 53rd frame period, sets of new display image data continue to be supplied to the image buffer 12f due to user operations on the input operation section 16 from the 51st frame period to the 55th frame period. In this case, the display image data D7 written in the FB area 12fB as the back buffer in the 52nd frame period is transferred from the FB area 12fA as the front buffer to the LCD in the 53rd frame period. However, since the LCD is still in the retuning state even at this point, this display image data D7 also is missing when transferring to the LCD (frame missing occurs). Also in the 53rd frame period, new display image data D8 is written into the FB area 12fA as the back buffer.

At the beginning of the 54th frame period, the LCD is in Normal State, and each circuit in the LCD resumes its operation. Therefore, the display image data D8 in the FB area 12fA as the front buffer is transferred to the LCD without missing, and the display image is refreshed by the display image data D8 in the LCD. Also in the 54th frame period, new display image data D9 is written into the FB region 12fB as the back buffer, and also in the 55th frame period, new display image data D10 is written into the FB region 12fA as the back buffer. The display image data D9 and D10 are sequentially transferred to the LCD without missing in the same manner and are used for refreshing the display image on the LCD.

It should be noted here that if the time point of returning from Intermission State 2 to Normal State is known beforehand, it is possible to avoid the frame missing as described above. That is, as shown in FIG. 13, if it is previously known that the LCD shifts from Normal State to Intermission State 2 during the 57th frame period and returns to Normal State during the 83rd frame period (for example, if there is no data update in the image buffer 12f until the refresh start timer times out), it is possible to transfer a return instruction to the LCD by a period (two frame periods in this example) corresponding to the returning state before (in the example, during the 81st frame period). As a result, even if multiple sets of display image data are sequentially supplied to the image buffer 12f after the 83rd frame period, new display image data D11 supplied in the 83rd frame period is written into the back buffer, during each of the 84th to 86th frame periods, new display image data Di+1 is written into the back buffer, while display image data Di written into the back buffer during the immediately preceding frame period is transferred to the LCD without causing frame missing and is used for refreshing the display image on the LCD (i=11, 12, 13). The display image data D14 written into the back buffer during the 86th frame period is transferred to the LCD during the 87th frame period and is used for refreshing the display image on the LCD.

### 1.7.2 Operation for Preventing of Frame Missing in the Present Embodiment

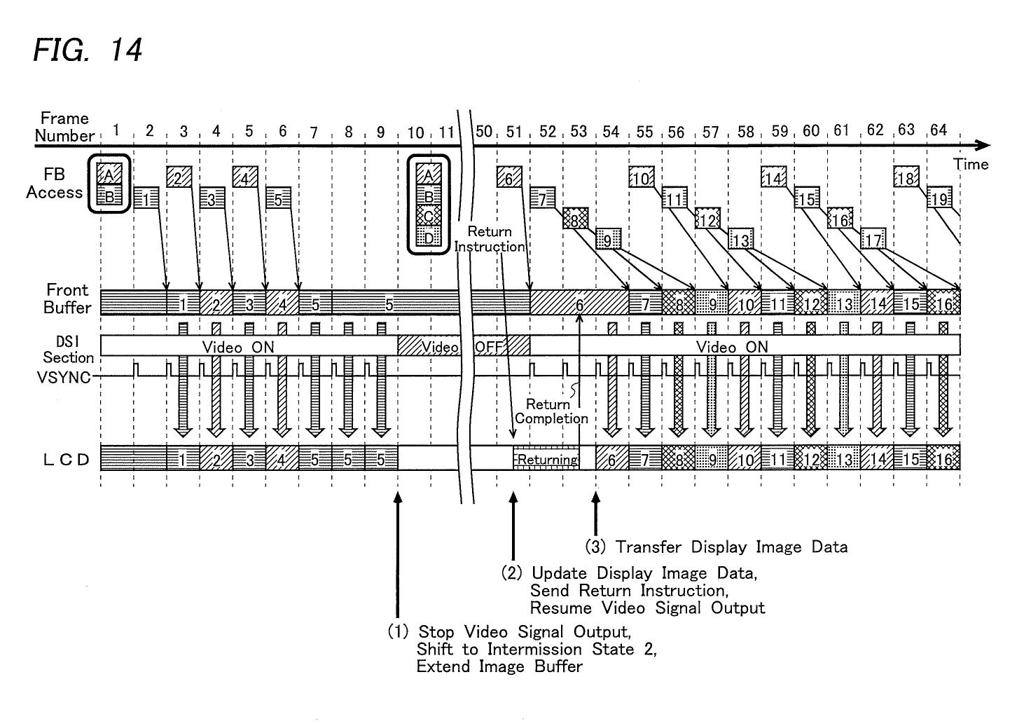

FIG. 14 is a timing chart for describing operation when returning from Intermission State 2 to Normal State through the returning state due to a data update in the image buffer 12f caused by a user operation on the input operation section 16, in the data processing device 100 according to the present embodiment. In Normal State, the image buffer 12f in the present embodiment is composed of two FB regions 12fA and 12fB (see FIG. 6), but in Intermission State 2, two FB regions 12fC and 12fD are added as an extension portion to form four FB regions 12fA to 12fD (see FIG. 7). As described above, one of the four FB areas 12fA to 12fD serves as a front buffer, the other three FB areas serve as back buffers, and the three back buffers are ranked. In FIG. 14, the FB area 12fA is identified by the symbol “A”, the FB area 12fB by the symbol “B”, the FB area 12fC by the symbol “C”, and the FB area 12fD by the symbol “D”. Also, the graphic (rectangle) indicating the FB area 12fA is hatched with slanted lines, the graphic indicating the FB area 12fB is hatched with horizontal lines, the graphic indicating the FB area 12fC is hatched with crossed-slanted lines (cross-hatching), and the graphic indicating the FB area 12fD is hatched with dots (the same applies to the other drawings).

In the example shown in FIG. 14, during the first frame period, the host and the LCD are in Normal State, the image buffer 12f is in an unextension state and is composed of two FB regions 12fA and 12fB, and during the second frame period, display image data D1 is written into the FB area 12fB serving as the back buffer. When the image buffer 12f is in the unextension state, the FB area as the back buffer and the FB area as the front buffer are alternately switched between the two FB areas 12fA and 112fB (see FIG. 6). During each frame period of the third to sixth frame periods, new display image data Di+1 is written into the back buffer, while display image data Di written into the back buffer during the immediately preceding frame period is read from the front buffer and is transferred to the LCD without frame missing to be used for refreshing the display image on the LCD (i=1 to 4). The display image data D5 written in the back buffer during the sixth frame period is transferred to the LCD in the seventh frame period to be used for refreshing the display image on the LCD.

During any of the eighth and ninth frame periods, new display image data is not written into the back buffer, but the display image data D5 stored in the front buffer is transferred to the LCD to be used for refreshing the display image in the LCD. When the 10th frame period starts, the update detection section 132 serving as an interrupt handler sends a no-update signal to the DSI controller 135 (Step S22 in FIG. 8). As a result, the DSI section 106 stops the output of the video signal (Video OFF) (Steps S36 through S40, S45), and based on a refreshing start preceding frame count REF_F calculated from driver status information acquired from the LCD, the host and the LCD Shift to Intermission State 2 (Steps S46 through S48, S54 through S60). In the present embodiment, when the host shifts to Intermission State 2, the image buffer 12f is extended (Step S54) and is composed of four FB regions 12fA to 12fD. When the image buffer 12f is in the extension state, one FB area as the front buffer and three FB areas as the first to third back buffers are sequentially circulated between the four FB areas 12fA to 12fD (See FIG. 7).

The host is set to be in Intermission State 2 until the refresh start timer times out according to the refreshing start preceding frame count REF_F after the 10th frame period (Steps S46 and S60). However, in the example shown in FIG. 14, during the 51st frame period before the timeout, new display image data D6 is supplied to the image buffer 12f due to a user operation on the input operation section 16 and is written into the FB area 12fA as the back buffer, which is detected as a data update in the image buffer 12f (Steps S12 and S14), so that a return instruction is sent from the host to the LCD (Steps S60 through S64).

Thereafter, (video driver 131 of) the host is in a waiting state until operation of the stopped circuits in the LCD is resumed and a return completion notification is received from the LCD. During the 52nd frame period in the waiting state, the FB area 12fA having the display image data D6 stored therein serves as the front buffer, and new display image data D7 is written into the FB area 12fB as the first back buffer due to a user operation on the input operation section 16. Also during the 53rd frame period, new display image data D8 is written into the FB area 12fC as the second back buffer due to a user operation on the input operation section 16.

Also, during the 53rd frame period, operation of each circuit in the LCD is resumed and a return completion notification is sent from the LCD to the host (Step S65). As a result, during the 54th frame period, the display image data D6 stored in the FB region 12fA as the front buffer is transferred to the LCD, and the display image of the LCD is refreshed with this display image data D6 (Steps S35, S34). Here, although a delay corresponding to the period of the returning state occurs with respect to the refreshment of the display image on the LCD, no frame missing occurs. Furthermore, during the 54th frame period, new display image data D9 is written into the FB area 12fD as the third back buffer due to a user operation on the input operation section 16.

Thereafter, while sets of new display image data are supplied to the image buffer 12f by user operations on the input operation section 16, for each frame period a set of display image data Dj is written into the image buffer 12f including the four FB areas 12fA to 12fD and a set of display image data Dj−3 is read from the same (j=10, 11, 12, . . . ) by the first-in first-out method.

As described above, according to the present embodiment, the image buffer 12f is extended in the host when shifting to Intermission State 2 (Step S54; FIG. 6, FIG. 7). Therefore, even in the case where it takes time to resume operation of each circuit in the LCD when returning from Intermission State 2 to Normal State, it is possible to write new display image data into the back buffer in the image buffer 12f while stopping transfer of the display image data to the LCD during the returning period. As a result, even in the case where it is impossible to predict the returning point from Intermission State 2 to Normal State, such as when a data update occurs in the image buffer 12f due to a user operation on the input operation section 16, it is possible to greatly reduce power consumption without degrading the display quality, by stopping many circuits of the LCD in Intermission State 2 without causing frame missing.

### <1.8 Release of Extension of Image Buffer>

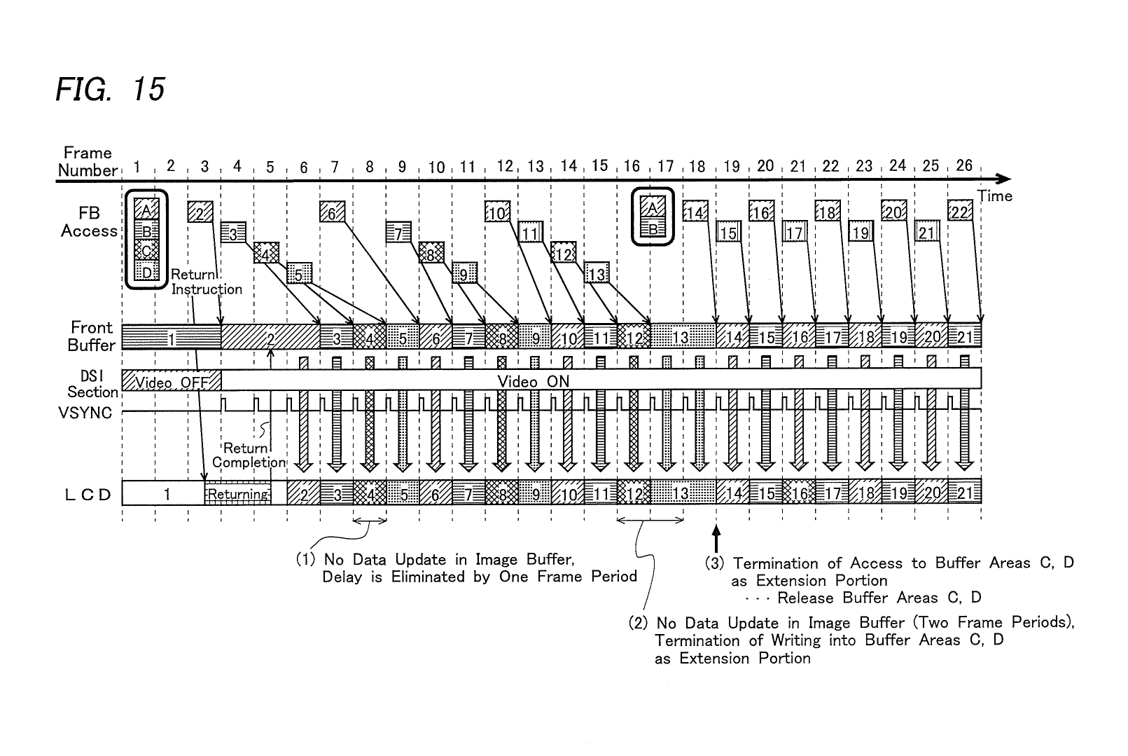

As described above, in the present embodiment, the image buffer 12f is extended when the host and the LCD shift from Normal State to Intermission State 2 ((1) in FIG. 14, FIG. 6→FIG. 7), and thereafter, it is possible to release the extension (extension state) of the image buffer 12f when there appear a plurality of frame periods (two or more frame periods in the present embodiment) without data update in the image buffer 12f. Hereinafter, with reference to FIG. 15, operation relating to the release of the extension of the image buffer 12f in the present embodiment will be described.

In the example shown in FIG. 15, in the first and second frame periods, the host and the LCD are in Intermission State 2, and the image buffer 12f is in an extension state and is composed of four FB regions 12fA to 12fD, of which the FB region 12fB stores display image data D1 as the front buffer.

In the third frame period, new display image data D2 supplied to the image buffer 12f due to a user operation on the input operation section 16 is written into the FB area 12fA as the back buffer, which is detected as a data update in the image buffer 12f, so that a return instruction is sent from the host to the LCD (Steps S60 through S64). After that, (video driver 131 of) the host is in a waiting state until operation of the stopped circuit in the LCD is resumed and a return completion notification is received from the LCD. The host measures duration of this waiting state, that is, time from sending of the return instruction till receiving of the return completion notification.

During the fourth frame period in the waiting state, the FB area 12fA having the display image data D2 stored therein serves as the front buffer, and new display image data D3 is written into the FB area 12fB as the first back buffer due to a user operation on the input operation section 16. During the fifth frame period as well, new display image data D4 is written into the FB area 12fC as the second back buffer due to a user operation on the input operation section 16.

During the fifth frame period, the return completion notification from the LCD is received by the host (Step S65). As a result, during the sixth frame period, the display image data D2 in the FB area 12fA as the front buffer is transferred to the LCD, and the display image of the LCD is refreshed with the display image data D2 (Steps S35, S34). Also during the sixth frame period, new display image data D5 is written into the FB area 12fD as the third back buffer due to a user operation on the input operation unit 16.

During the seventh frame period, new display image data D6 is written into the FB region 12fA as the first back buffer, and the display image data D3 in the FB region 12fB as the front buffer is transferred to the LCD.

During the eighth frame period, the display image data D4 is read out from the FB region 12fC as the front buffer and is transferred to the LCD, but no new display image data is supplied to the image buffer 12f. The host counts the number of frame periods (hereinafter referred to as “non-update frame periods”) during which there is no data update in the image buffer 12f such as the eighth frame period by using the above-described second no-update variable Jnup (See Step S18 in FIG. 8, Step S68 in FIG. 10). Since there is no data update in the image buffer 12f during the eighth frame period, the delay of refreshment of the display image on the LCD is eliminated by one frame period ((1) in FIG. 15).

During the ninth through fifteenth frame periods, sets of new display image data are supplied to the image buffer 12f due to user operations on the input operation section 16, and for each frame period a set of display image data Dj is written into the image buffer 12f including the four FB areas 12fA to 12fD and a set of display image data Dj−2 is read from the same (j=7 to 13) by the first-in first-out method.

During the sixteenth frame period, the display image data D12 is read out from the FB region 12fC as the front buffer and transferred to the LCD. During the seventeenth frame period, the display image data D13 is read out from the FB region 12fD as the front buffer and transferred to the LCD. During any of the sixteenth and seventeenth frame periods, no new display image data is supplied to the image buffer 12f. Therefore, the number of no-update frame periods (the count value by the host), that is, the second no-update variable Jnup becomes equal to or larger than the number of return time frames Nrt (“2” in the present embodiment) and writing into the FB areas 12fC and 12fD is temporarily terminated ((2) in FIG. 15). Since the FB region 12fC serves as the front buffer during the sixteenth frame period and the FB region 12fD serves as the front buffer during the seventeenth and eighteenth frame periods, the FB regions 12fC and 12fD as the extension portion are not released.

During the eighteenth frame period, new display image data D14 is written into the FB area 12fA as the back buffer due to a user operation on the input operation section 16, and the display image data 1D13 in the FB area 12fD as the front buffer is transferred to the LCD. As a result of this transfer, access to the FB areas 12fC, 12fD as the extension portion of the image buffer 12f is completed, and therefore the FB areas 12fC, 12fD are released after this transfer ((3) in FIG. 15, Step S38 in FIG. 9).

During each frame period after the nineteenth frame period, new display image data Di+1 is written into the back buffer and display image data Di written into the back buffer during the preceding frame period is transferred to the LCD (i=14, 15, 16, . . . ), while new display image data are being supplied to the image buffer 12f due to user operations on the input operation section 16. Since the image buffer 12f is composed of the two FB areas 12fA and 12fB in the 19th frame period and thereafter, the FB area as the back buffer and the FB area as the front buffer are alternately switched between the two FB areas 12fA and 112fB. It is to be noted that the access to such an unextended image buffer 12f is also in accordance with the first-in first-out method like the access to the image buffer 12f in the extension state.

According to the above configuration of the present embodiment, the extension portion of the image buffer 12f extended to prevent the frame missing in the returning state of the LCD is released, when the no-update frame period occurs the number of times which corresponds to the return time (the number of return time frames Nrt) in Normal State. For this reason, it is possible to avoid consuming extra memory in the host in order to prevent frame missing.

### 1.9 Operation Example

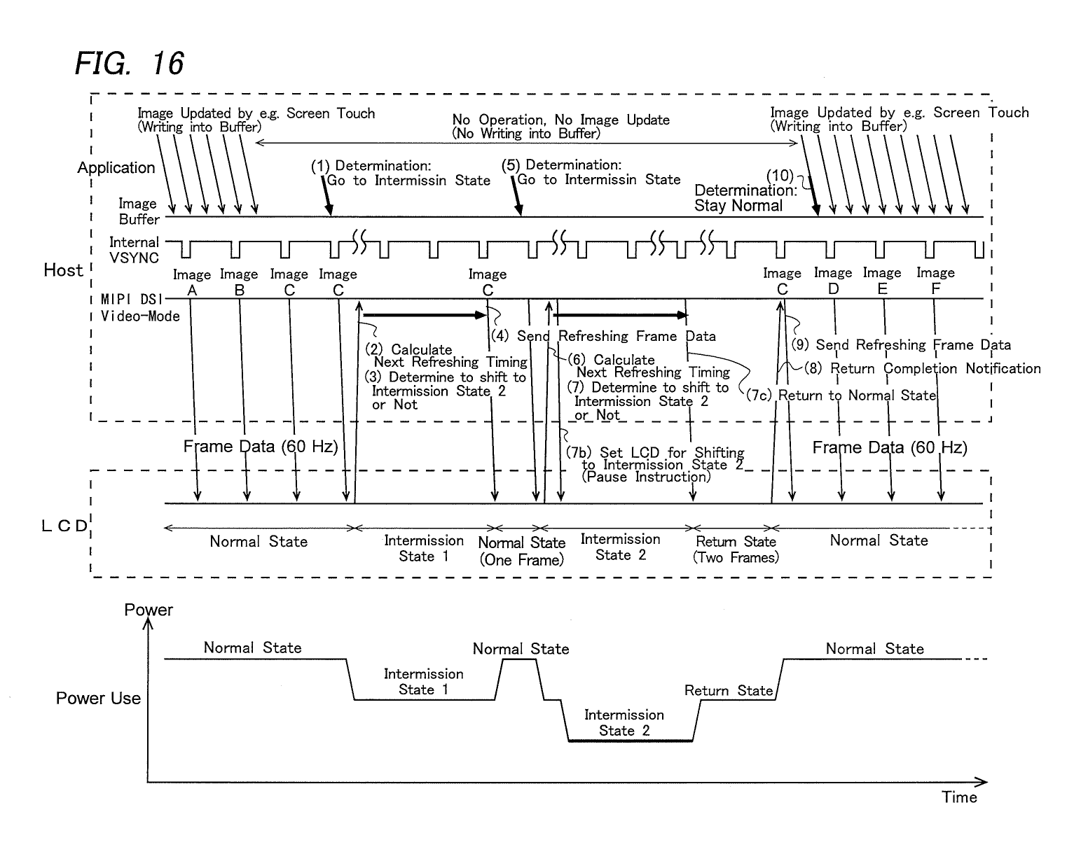

FIG. 16 is a sequence diagram and timing chart which shows a concrete operation example according to the present embodiment. Hereinafter, the present operation example will be described with reference to FIG. 16, together with FIGS. 9 and 10, etc.

As shown in FIG. 16, in Normal State, if a user makes an operation on the input operation section 16 (such as touch panel) of a portable terminal (FIG. 1) which includes the data processing device according to the present embodiment, and causes a data update in the image buffer 12f, the update triggers sets of new display image data representing Images A, B and C respectively to be transferred sequentially, one at a frame period, to the LCD via an interface conforming to MIPI-DSI Standards.

Thereafter, when there is no more user operation made to the input operation section 16 and therefore there is no more data update in the image buffer 12f, then shifting to Intermission State (Intermission State 1 or 2) is determined; whereupon LCD driving information is obtained from the LCD, and the refreshing start preceding frame count REF_F is calculated from the LCD driving information (more specifically, from a non-refreshing count, etc. contained in the information) (Steps S32 and S39; (1) and (2) in FIG. 16). Thereafter, video signal output from the DSI section 106 is stopped, and the refreshing start timer is set so as to time out upon elapse of a time equivalent to the refreshing start preceding frame count REF_F (Steps S45 and S46)

Next, based on the refreshing start preceding frame count REF_F, determination is made as to whether or not conditions are met for shifting to Intermission State 2 (Step S48; (3) in FIG. 16). In this example, it is determined that the conditions are not met, so the host and the LCD shift to Intermission State 1 (Step S52).

Thereafter, when the refreshing start timer times out, video signal output by the DSI section 106 is resumed; the host and the LCD return to Normal State; and in order to refresh the display image in the LCD, refreshing frame data (data representing the display image C) is sent from the host to the LCD (Steps S35 and S34; (4) in FIG. 16).

Thereafter, it is determined again whether or not a data update occurs in the image buffer 12f; but at this point again, there is no user operation made into the input operation section 16, so it is determined to shift to Intermission State (Intermission State 1 or 2), and the refreshing start preceding frame count REF_F is calculated from the LCD driving information obtained from the LCD (Steps S32 and S39; (5) and (6) in FIG. 16). Thereafter, video signal output from the DSI section 106 is stopped, and the refreshing start timer is set so as to time out upon elapse of a time equivalent to the refreshing start preceding frame count REF_F (Steps S45 and S46)

Next, based on the refreshing start preceding frame count REF_F, determination is made as to whether or not conditions are met for shifting to Intermission State 2 (Step S48) ((7) in FIG. 16). In this example, it is determined that the conditions are met, so the host and the LCD shift to Intermission State 2 (Steps S54 through S60). At this point, the refreshing start timer is set, the image buffer 12f is extended (Step S54; FIG. 6→FIG. 7), and instructions are sent to the LCD for bringing the LCD into Intermission State 2 (Step S58; (7b) in FIG. 16), and then the DSI controller 135 in the host assumes a sleep state (Step S60).

Thereafter, when the refreshing start timer times out, the DSI controller 135 in the host returns to an active state, and information necessary for the next refreshing of the display image in the LCD (information and instructions for bringing the LCD back into Normal State) are sent to the LCD (Steps S62, S64; (7c) in FIG. 16). It should be noted here that there are some cases where as shown in FIG. 14 a data update occurs in the image buffer 12f due to a user operation on the input operation section 16 before the timeout of the refreshing start timer, whereby the DSI controller 135 in the host returns to an active state and a return instruction is sent from the host to the LCD (this also applies to all the other embodiments).

After the return instruction is sent from the host to the LCD, the host assumes a waiting state until receiving a return completion notification from the LCD (Step S65). Thereafter, upon receiving the return completion notification from the LCD ((8) in FIG. 16), the LCD driving information is sent to the LCD (Step S67).

Further thereafter, video signal output by the DSI section 106 is resumed; the host and the LCD return to Normal State; and in order to refresh the display image in the LCD, refreshing frame data (data representing the display image C) is transferred from the host to the LCD (Steps S35 and S34; (9) in FIG. 16).

In the present operation example, when this transfer of the refreshing frame data is coming to its end, the user begins to make operation on the input operation section 16, and so it is determined that a data update in the image buffer 12f occurs (Step S32; (10) in FIG. 16). As a result, the update triggers, sets of new display image data, i.e., data representing Images D, E and F, . . . to be transferred sequentially, one at a frame period, to the LCD (Steps S32 and S34).

### 1.10 Advantages

According to the present embodiment described above, if the display device 11 (LCD) which is connected with the data processing device 100 (host) is operating in the intermission driving mode, the next refreshing timing is determined based on the refreshing start preceding frame count REF_F which is calculated from LCD driving information such as a non-refreshing count, obtained from the LCD, and the host (DSI controller 135 thereof) assumes a sleep state until the next refreshing (Steps S32, S39, S46 and S52; see FIG. 12, etc.) Therefore, host-side processing for monitoring a REQUEST signal is unnecessary in the present embodiment, the REQUEST signal being required in the conventional configuration in which the REQUEST signal requesting transfer of the image data for refreshing is sent from the display device to the host. On the other hand, since the refreshing start preceding frame count REF_F is calculated from LCD driving information obtained from the LCD, it is possible to perform display image refreshing according to the needs of the LCD at an appropriate timing by taking characteristics of the LCD and driving state thereof into account. Therefore, it is possible to decrease power consumption not only in the LCD but also in the host while ensuring high display quality in the LCD in the intermission driving mode. It should be noted here that the update detection section 132 as an interrupt handler is started every frame period regardless of whether or not the DSI controller 135 in the video driver 131 is in asleep state or not; however, the time necessary for this procedure is so short that the operation of the update detection section 132 poses no problem in view of power consumption in the host.

Also, according to the present embodiment, the host determines whether or not to shift to Intermission State, i.e., whether or not the image to be displayed is changed or not, based on a data update monitoring at the image buffer 12f (see FIGS. 2, 8 and 9); this eliminates the need for the LCD to detect for image changes. Hence, the present embodiment also contributes to decrease in power consumption in the LCD.

Further, in the present embodiment, each time a shift is made to the Intermission State, the next refreshing start timing of the display image is determined based on LCD driving information from the LCD. This makes it possible to significantly reduce power consumption at the host even in comparison with the conventional example in which data for refreshing is sent from the host to the LCD at a predetermined time interval if there is non-update in display image.

According to the present embodiment, Intermission State of the LCD consists of two levels, i.e., Intermission State land Intermission State 2. If the refreshing start preceding frame count REF_F which is calculated from LCD driving information is not greater than a predetermined value (“10” in the present embodiment), Intermission State 1 is selected (Step S52) which allows for quick return to Normal State when there is any change found in the image to be displayed and the changed image must be displayed in the LCD. If the refreshing start preceding frame count REF_F is greater than the predetermined value, it is assumed that there will be a lower probability for bringing the sleeping LCD back to Normal State, and the LCD is shifted to Intermission State 2 (Step S48, S54 through S60; see (B) of FIG. 12), where the LCD's power consumption is decreased by a greater amount than in Intermission State 1. This offers a greater power saving advantage for those display devices which are capable of extending their refreshing interval when display image is not updated (see the timing chart of the power use shown in FIG. 16). It should be noted here that while the present embodiment and the other embodiment which will be described later make use of a two-level Intermission State consisting of Intermission State 1 and Intermission State 2, Intermission State may consists of three or more levels.

According to the present embodiment, when shifting to Intermission State 2, the image buffer 12f is extended in the host (step S54; FIG. 6→FIG. 7). Therefore, even in the case where it takes time to resume operation of each circuit in the LCD when returning from Intermission State 2 to Normal State, it is possible to write new display image data into a back buffer in the image buffer 12f while stopping transfer of the display image data to the LCD during the returning period. As a result, even in the case where it is impossible to predict the returning point from Intermission State 2 to Normal State, such as when a data update occurs in the image buffer 12f due to a user operation on the input operation section 16, it is possible to greatly reduce power consumption without degrading the display quality, by stopping many circuits of the LCD in Intermission State 2 without causing frame missing. Furthermore, the extension portion of the image buffer 12f which is extended when shifting from Normal State to Intermission State 2 is released, when no-update frame period occurs a predetermined number of times after that (Steps S18, S37, S38; FIG. 15). Therefore, it is possible to avoid consuming extra memory in the host in order to prevent frame missing.

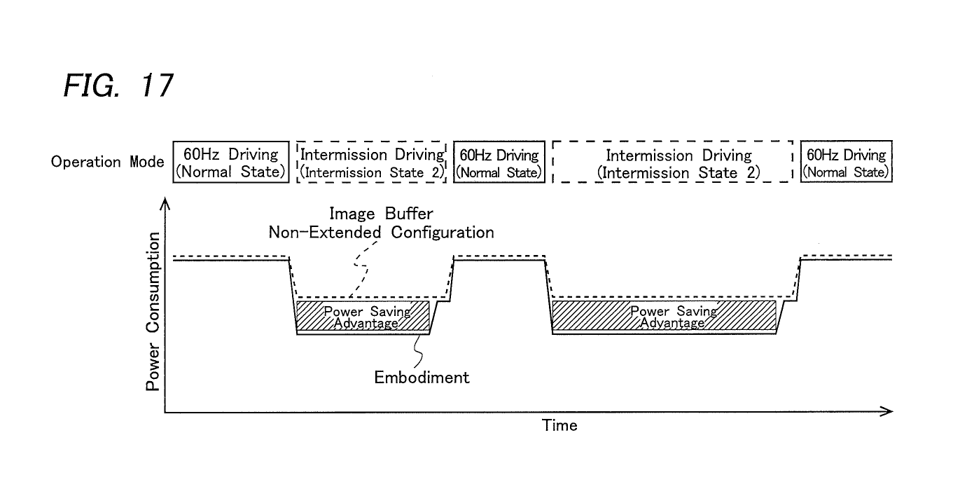

FIG. 17 is a diagram showing the effect (power saving advantage) of reducing the power consumption of the display device 11 (LCD) according to the present embodiment as described above. More specifically, FIG. 17 illustrates changes in the power consumption in the case where the operation mode is switched between the 60 Hz driving (Normal State) in which the display image is refreshed at 60 Hz and the intermission driving in which Intermission State 2 is included. In FIG. 17, dotted line shows the changes in the power consumption of the display device (LCD) when the image buffer 12f in the host has the non-extended configuration, and solid line shows the changes in the power consumption of the display device 11 (LCD) according to the present embodiment. Hatched rectangles schematically show the degree of the power saving advantage of the present embodiment over the case where the image buffer is non-extended. In the case where the image buffer is in a non-extended configuration, the stopped circuits in the display circuit in Intermission State are limited so that the time required for the display device to return from Intermission State 2 to Normal State is a predetermined value or less from the viewpoint of prevention of frame missing. By contrast, in the present embodiment, the image buffer 12f is extended so as to be able to cope with a data update in the image buffer in the process of the display device 11 (LCD) returning from Intermission State 2 to Normal State (Step S54 in FIG. 10; FIG. 6→FIG. 7). Therefore, it is possible to stop more circuits in the display device 11 in Intermission State 2. For this reason, as shown in FIG. 17, in the present embodiment, the power consumption of the display device 11 performing the intermission driving can be greatly reduced as compared with the case where the image buffer is not extended.

### 2. Second Embodiment

Next, description will cover a data processing device according to a second embodiment of the present invention. Like the first embodiment, this data processing device is also used in a portable terminal configured as shown in FIG. 1. The data processing device according to the present embodiment which is connected with a display device has primarily the same system configuration (hardware and software configurations) as in the first embodiment (FIG. 2); however, there are a few differences (which will be described later). The display device and its display control circuit are identical with those in the first embodiment (FIGS. 3 and 4). Therefore, among these hardware and software components of the present embodiment, those which are identical with or corresponding to the components in the first embodiment will be indicated with the same reference symbols, without repeating detailed descriptions thereof.

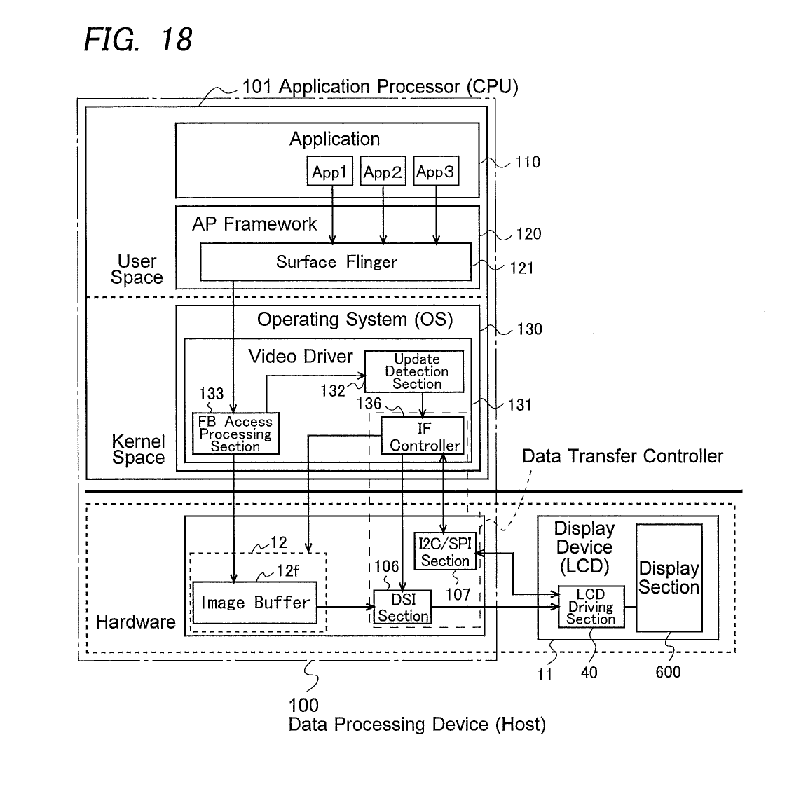

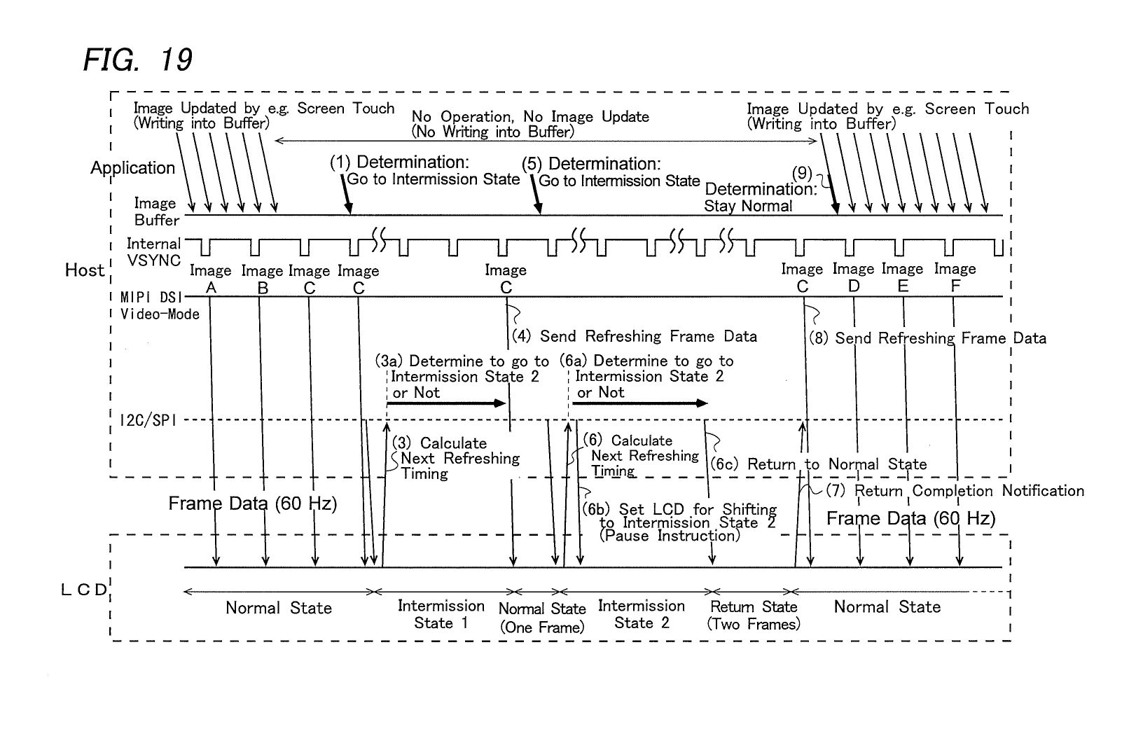

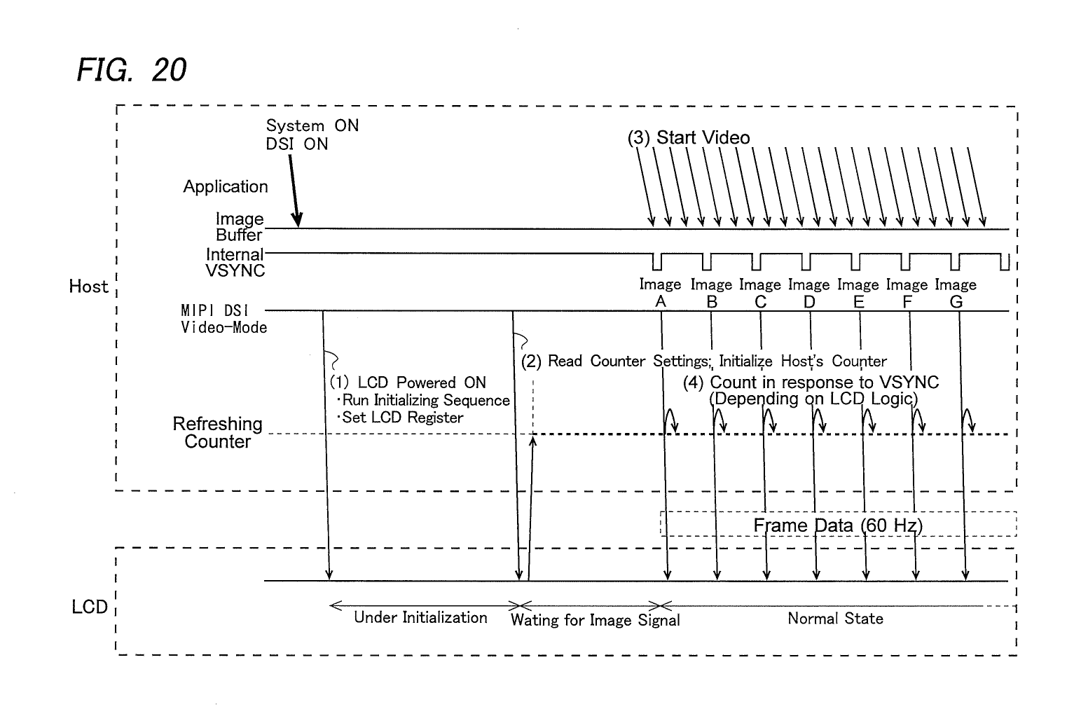

FIG. 18 is a block diagram which shows a system configuration of a data processing device 100 according to the present embodiment, connected with a display device 11. Whereas the first embodiment makes use of commands and interface which conform to MIPI-DSI Standards (hereinafter called “DSI interface”) to give instructions to the display device 11 (LCD), to transfer setting information, and to obtain driving information, etc. from the LCD in the first embodiment, the present embodiment makes use of an interface which conforms to I2C Standards or SPI Standards (hereinafter called “I2C/SPI interface”) in these transfer operation and information acquisition. Therefore, as shown in FIG. 18, the data processing device 100 includes an I2C/SPI section 107 provided by an I2C/SPI interface as a host-side interface circuit, in addition to the DSI section 106 provided by a DSI interface. Accordingly, the DSI controller 135 which serves as an interface controller for the video driver 131 in the first embodiment is replaced by an IF controller 136 in the present embodiment. However, a processing procedure of a program for implementing the IF controller 136 is substantially the same, differing only in that the I2C/SPI interface is used in place of the DSI interface in obtaining LCD information from the display device 11 and giving instructions, etc. to the display device 11 (Steps S39, S56, S58, S64, S65 and S67) (see FIGS. 9 and 10). For this reason, hereinafter, reference to such drawings as FIGS. 9 and 10 will also be made in describing the present embodiment using FIG. 19 which corresponds to FIG. 16 that shows an operation example of the first embodiment. As a note for the present embodiment, the DSI section 106 and the I2C/SPI section 107 working as interface circuits constitute the data transfer controller, together with the IF controller 136 working as an interface controller.

FIG. 19 is a sequence diagram which shows an operation example according to the present embodiment. In this operation example, like the operation example in the first embodiment shown in FIG. 16, when there is no user operation made into the input operation section 16 (e.g., touch panel), and therefore there is no more data update in the image buffer 12f, then shifting to Intermission State (Intermission State 1 or 2) is determined; whereupon LCD driving information is obtained from the LCD, and the refreshing start preceding frame count REF_F is calculated from the LCD driving information (more specifically, from a non-refreshing count, etc. contained in the information) (Steps S32 and S39; (1) and (3) in FIG. 19). A difference, however, is that LCD driving information which is obtained via a DSI interface in the first embodiment (see FIG. 16), is obtained via an I2C/SPI interface in the present embodiment (see FIG. 19 and FIG. 5). Thereafter, based on the refreshing start preceding frame count REF_F which is calculated from the obtained LCD driving information, determination is made as to whether or not conditions are met for shifting to Intermission State 2 (Step S48; (3a) in FIG. 19).

Thereafter, when there is no data update in the image buffer 12f and therefore shifting to Intermission State (Intermission State 1 or 2) is determined again, then LCD driving information is obtained from the LCD not via the DSI interface but via the I2C/SPI interface (Steps S32 and S39; (5) and (6) in FIG. 19), and determination is made as to whether or not the conditions for shifting to Intermission State 2 are met, based on the refreshing start preceding frame count REF_F which is calculated from the said LCD driving information (Step S48; (6a) in FIG. 19). In this example, it is determined that the conditions are met, so the host and the LCD shift into Intermission State 2 (Steps S54 through S60). At this point, the refreshing start timer is set, the image buffer 12f is extended (Step S54; FIG. 6→FIG. 7), and instructions for bringing the LCD into Intermission State 2 are sent to the LCD (Steps S54 and S58). In the present embodiment, the instructions are sent to the LCD not via the DSI interface but via the I2C/SPI interface ((6b) in FIG. 19).

Thereafter, when the refreshing start timer times out, information necessary for the next refreshing of the display image in the LCD (namely, information and instructions for bringing the LCD back into Normal State) are sent to the LCD, the host waits until it receives a return completion notification from the display device 11 (Steps S62 through S65; (6c) in FIG. 19). Upon receiving the return completion notification ((7) in FIG. 19), LCD driving information is sent to the display device 11 (Step S67) so as to be re-set therein. In the present embodiment, the reception of the return completion notification as well as the transmission of the information and instructions are performed not via the DSI interface but via the I2C/SPI interface.

Other than the above-described differences, specifics in the present operation example are identical with those in the operation example of the first embodiment shown in FIG. 16. Therefore, transfer of display image data such as refreshing frame data to the LCD is performed via the DSI interface as shown in FIG. 19, in the present operation example.

As understood from the description made above, exchange of data (information and instructions) are made entirely via the DSI interface in the first embodiment, but in the present embodiment, transfer of instructions and setting information to the LCD, and obtainment of driving information from the LCD are made via the I2C/SPI interface (see (3), (6), (6b), (6c), and (7) in FIG. 19). However, operations in the present embodiment are substantially the same as those in the first embodiment. Therefore, the present embodiment offers the same advantages as offered by the first embodiment. In the present embodiment, the second interface circuit is provided as a serial interface having a slower data transfer speed than the first interface circuit. This can offer an additional advantage of decreased power consumption in data transfer between the data processing device and the display device through selective use of the first interface circuit and the second interface circuit depending on the amount of data transfer.

### 3. Third Embodiment

Next, description will cover a data processing device according to a third embodiment of the present invention. Like the first embodiment, this data processing device is also used in a portable terminal configured as shown in FIG. 1. The data processing device and display device included in this portable terminal have the same system configuration (hardware and software configurations) as in the first embodiment (FIG. 2). Further, the display device and its display control circuit have basically the same configurations as in the first embodiment (FIGS. 3, 4, 5). Therefore, among these hardware and software components of the present embodiment, those which are identical with or corresponding to the components in the first embodiment will be indicated with the same reference symbols, without repeating detailed descriptions thereof.

In the first embodiment, the LCD's display control circuit 200 includes the counter 35a which counts the number of frames having an image which has no change, i.e., the number of frames of a still image, as the non-refreshing frame count (see FIG. 5) in order to obtain refreshing timing of a display image in the display device 11 (LCD). In the present embodiment, the function of the counter 35a, i.e., the function as a counter to count the non-refreshing frame count (hereinafter called “refreshing counter”) is provided by the data processing device 100 working as the host. This refreshing counter is implemented by software, within the host as will be described later. It should be noted here that the refreshing counter gives the earlier-described non-refreshing count, and the value is reset to “0” when the display image is refreshed in the LCD.

FIG. 20 is a drawing for describing operation immediately after an initialization sequence of the host and the LCD when electric power is turned on in the present embodiment. Operation of the refreshing counter is different depending on the LCD. Therefore, in the present embodiment, counter setting parameters which specify the operation of the refreshing counter to match the display device 11 (LCD) connected with the data processing device 100 working as the host are obtained from the display device 11 (LCD) right after the initialization sequence following the power ON ((1) and (2) in FIG. 20). Since the refreshing counter is utilized to determine the timing for the next refreshing of the displayed image, the counter setting parameters can be regarded as refreshing-related information.

The counter setting parameters are thus obtained and then, if a user makes an operation on the input operation section 16 (such as touch panel) whereby a data update occurs in the image buffer 12f, the host and the LCD assume Normal State, and the video driver 131 which includes the DSI controller 135 and the update detection section 132 operates basically as shown in the flow charts in FIG. 8 through FIG. 10. Therefore, if a user makes an operation on the input operation section 16 in Normal State whereby a data update occurs in the image buffer 12f, the update causes, as shown in FIG. 20, sets of new display image data, representing Images A, B, C respectively to be transferred sequentially, one at a frame period, to the LCD via the DSI interface.

Also, the non-refreshing count is updated or reset based on the counter setting parameters at the DSI controller 135 or the update detection section 132 in the video driver 131. If the host shifts to Intermission State, the non-refreshing count is corrected when returning from Intermission State to Normal State (Step S62). As has been described, the refreshing counter is implemented by software in the video driver 131 of the host. Therefore, the present embodiment does not require Steps S39 and S56 in the operation of the DSI controller 135 for obtaining the non-refreshing count as LCD driving information.

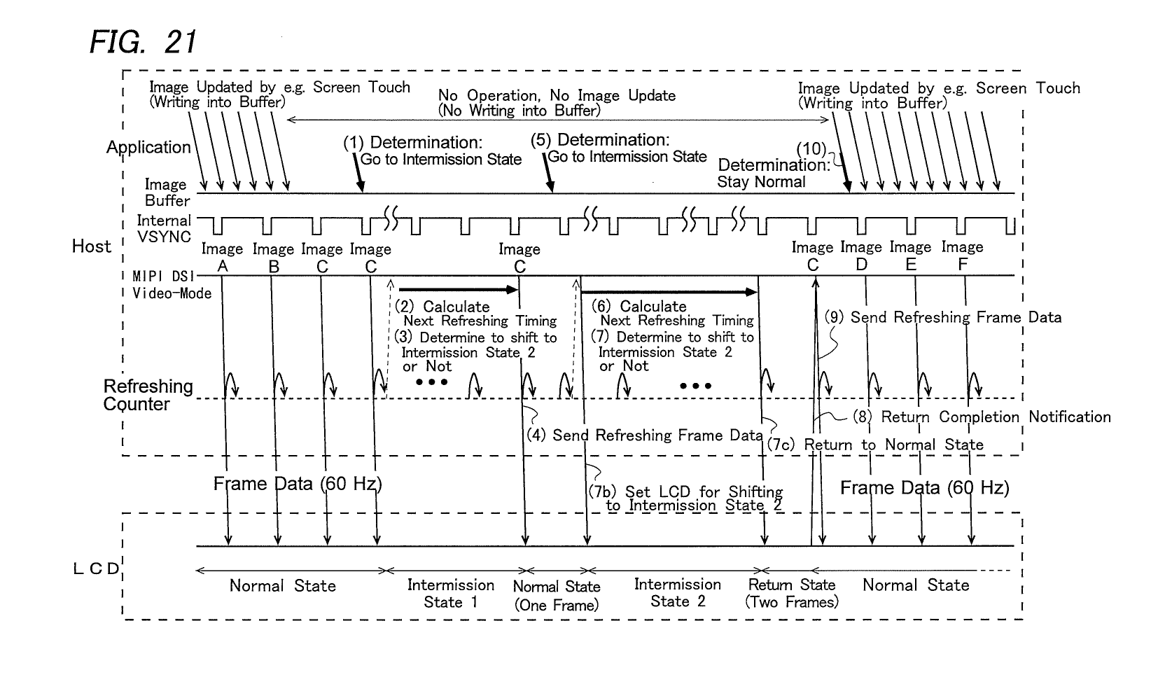

Next, reference to such drawings as FIGS. 9 and 10 will also be made in describing the present embodiment using FIG. 21 which corresponds to FIG. 16 that shows an operation example of the first embodiment.

FIG. 21 is a sequence diagram which shows an operation example according to the present embodiment. In this operation example, like the operation example in the first embodiment shown in FIG. 16, when there is no user operation made on the input operation section 16 and there is no more data update in the image buffer 12f, then shifting to Intermission State (Intermission State 1 or 2) is determined (Steps S32, S39, and S40; (1) in FIG. 21). Now, in the first embodiment, the refreshing start preceding frame count REF_F is calculated from the non-refreshing count, etc. contained in the LCD driving information which is obtained from the LCD (Step S39); in the present embodiment, however, the refreshing start preceding frame count REF_F is calculated from a value, i.e., a non-refreshing count, supplied by the refreshing counter which is implemented by software ((2) in FIG. 21). Thereafter, based on the refreshing start preceding frame count REF_F, determination is made as to whether or not conditions are met for shifting to Intermission State 2 (Step S48; (3) in FIG. 21).

Thereafter, when there is no data update in the image buffer 12f and therefore shifting to Intermission State (Intermission State 1 or 2) is determined again, then LCD driving information including the non-refreshing count is not obtained from the LCD but the refreshing start preceding frame count REF_F is calculated ((6) in FIG. 21) from the non-refreshing count which is a value from the refreshing counter inside the host, and determination is made as to whether or not the conditions for shifting to Intermission State 2 are met, based on this refreshing start preceding frame count REF_F (Step S48; (7) in FIG. 21). In this example, it is determined that the conditions are met, so the host and the LCD shift into Intermission State 2 (Steps S54 through S60). At this point, the refreshing start timer is set, the image buffer 12f is extended (Step S54; FIG. 6→FIG. 7), and instructions for bringing the LCD into Intermission State 2 are sent to the LCD (Step S58; (7b) in FIG. 21).

Thereafter, when the refreshing start timer times out, information necessary for the next refreshing of the display image in the LCD (information and instructions for bring the LCD back into Normal State) are sent to the LCD (Steps S62 through S66; (7c) in FIG. 14), the host waits until it receives a return completion notification from the display device 11 (Steps S62 through S65; (6c) in FIG. 19). Upon receiving the return completion notification ((7) in FIG. 19), LCD driving information is sent to the display device 11 (Step S67).

Other than the above-described differences, specifics in the present operation example are substantially the same as those in the operation example of the first embodiment shown in FIG. 16.

According to the present embodiment described above, since the host has a function of the refreshing counter, it is possible to obtain the timing of the next refreshing of the display image in the LCD at the host as shown in FIG. 21, without obtaining LCD driving information such as the non-refreshing count (the number of frames in the non-refreshing period). This eliminates the need for information exchange between the host and the LCD regarding the refreshing timing and makes refreshing control of the LCD simpler while offering the same power saving advantages as offered by the first embodiment.

Also, according to the present embodiment, counter setting parameters which specify operation of the refreshing counter to match the LCD connected with the host are obtained by the host in an initialization sequence. This makes it possible to refresh the display image in a manner suitable for characteristics and driving state of the LCD while allowing the host to centrally manage the display image refreshing in the LCD.

In the present embodiment, the function of the refreshing counter is implemented in the host by means of software. In addition to this, there may be an arrangement in which the function of the polarity imbalance counter is also implemented in the host by means of software. This makes it possible to determine the next refreshing timing of the display image while taking the polarity imbalance count into consideration, in addition to the non-refreshing count.

### 4. Fourth Embodiment

Next, description will cover a data processing device according to a fourth embodiment of the present invention. Like the first embodiment, this data processing device is also used in the portable terminal having the configuration shown in FIG. 1. The system configuration (the configuration of hardware and software) of the data processing device and the display device included in this portable terminal is the same as in the first embodiment (FIG. 2). Further, the display device and its display control circuit have basically the same configurations as in the first embodiment (FIGS. 3, 4, 5). Therefore, among these hardware and software components of the present embodiment, those which are identical with or corresponding to the components in the first embodiment will be indicated with the same reference symbols, without repeating detailed descriptions thereof.

In the first embodiment described above, a size of the extension portion of the image buffer 12f extended to prevent frame missing in the returning state of the display device 11 (LCD) is determined in advance (in the example shown in FIG. 7, it is an area for two frames). On the other hand, in the present embodiment, time from receiving of the return instruction till completing of the return in the LCD (duration of the returning state) is measured as a return time, and based on the measurement value (return time measurement value) the size of the extension portion of the image buffer 12f is determined. In the present embodiment, any one of a first method and a second method described below is adopted as a method for determining the size of the extension portion of the image buffer 12f.

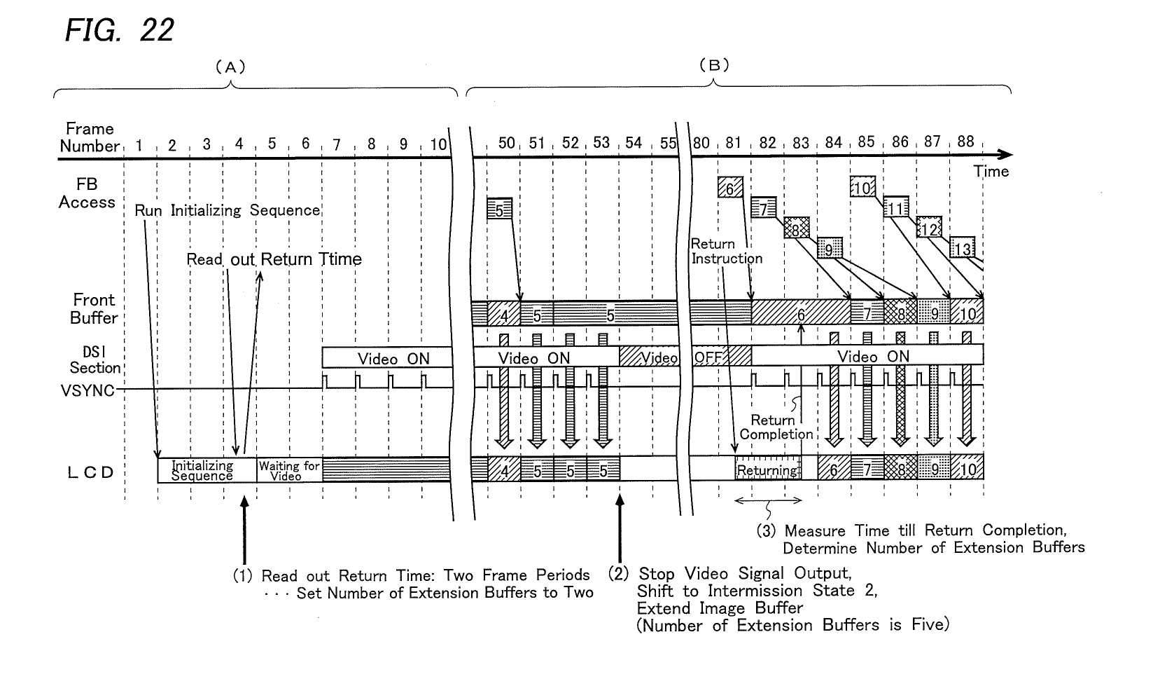

FIG. 22 is a timing chart for describing operation (hereinafter referred to as “extension size determination operation”) for determining the size of the extension portion of the image buffer in the present embodiment. More specifically, (A) of FIG. 22 shows operation of determining the extension size when the first method is adopted, and (B) of FIG. 22 shows operation of determining the extension size when the second method is adopted. As for the extension size determination operation in the present embodiment, only the operation shown in (A) of FIG. 22 is performed when the first method is adopted, and only the operation shown in (B) of FIG. 22 when the second method is adopted.

When the first method is adopted in the present embodiment, as shown in (A) of FIG. 22, in the initialization sequence of the LCD after the power is turned on, a measurement value of the return time which is read from the LCD in response to a request from the host is transferred to the host, and the DSI controller 135 in the host compares the measurement value in units of one frame period with the size of the extension portion of the image buffer 12f (hereinafter referred to as “image buffer extension size”). Here, it is assumed that the return time measurement value read out from the LCD is two frame periods, and two frames are held as the image buffer extension size. Upon completion of the initialization sequence, the DSI section 106 starts operation (Video ON). The operation related to updating and transferring the display image data thereafter as well as extending the image buffer 12f and releasing its extension are the same as those in the first embodiment (see FIGS. 14 and 15). Incidentally, instead of measuring the return time in the LCD, it is also possible to previously store an estimated return time in the LCD (NVM 38), and use this estimated return time instead of the measurement value of the return time as described above.

Next, with reference to (B) of FIG. 22, description will be made on the operation of determining the extended size in the case where the second method is adopted in the present embodiment. In the example shown in (B) of FIG. 22, sets of display image data D1 to D5 which are sequentially supplied to the image buffer 12f are transferred to the LCD in the state (Video ON) in which the DSI section 106 is operating, but in and after the 51st frame period, the state in which there is no data update in the image buffer 12f continues. Therefore, the operation of the DSI unit 106 is stopped during the 54th frame period (Video OFF). Here, based on the refreshing start preceding frame count REF_F calculated from the driver status information acquired from the LCD, the host and the LCD shift to Intermission State 2 (Steps S46 through S48, S54 through S60). At this time, the image buffer 12f is extended, and the size of the extension portion is set to an initial value of the image buffer extension size. The maximum number of frames assumed on the host side is preset as this image buffer extension size, and here, this initial value is five frames. After the 54th frame period, a state in which the display image data is not transferred to the LCD continues.

Thereafter, during the 81st frame period, new display image data D6 supplied to the image buffer 12f due to a user operation on the input operation section 16 is written into the FB area 12fA as a back buffer, and a return instruction is sent from the host to the LCD (Steps S60 through S64). Thereafter, the host waits until it receives a return completion notification from the LCD (Step S65).

Here, (the DSI controller 135 of) the host measures duration of the waiting state, that is, time from sending of the return instruction till receiving of the return completion notification, as a return time. For example, when the return instruction is sent to the LCD in Step S64 of FIG. 10, a time measurement timer is started, and in step S65, an output value of the time measurement timer at the time of receiving the return completion notification from the LCD is obtained, whereby the return time is measured. Assuming that the return time measurement value at this time corresponds to two frame periods, the host determines that the image buffer extension size is two frames at this point, and changes FB areas to be allocated besides one FB area as a front buffer and one FB area as a back buffer, from five FB areas to two FB areas. In the following, when the image buffer 12f is extended after the extension portion is released, the size of the extension portion is two frames.

In the example shown in (B) of FIG. 22, the return completion notification is sent from the LCD to the host in the 83rd frame period, and no display image data is transferred to the LCD until the 83rd frame period. However, sets of new display image data D 7, D 8, D 9, . . . are sequentially supplied to the image buffer 12f also in and after the 82th frame period.

In the 84th frame period, transfer of the display image data from the host to the LCD is restarted. While sets of new display image data are supplied to the image buffer 12f due to user operations on the input operation section 16 after the 84th frame period, for each one frame period a set of display image data Dj is written into the image buffer 12f including the four FB areas 12fA to 12fD (the image buffer 12f including the extension portion of two frames) and a set of display image data Dj−3 is read from the same (j=9, 10, 11, . . . ) by the first-in first-out method.

According to the present embodiment as described above, the size of the extension portion of the image buffer 12f extended to prevent frame missing in the returning state of the display device 11 (LCD) is determined based on the measurement result of duration of the returning state. Therefore, it is possible to reliably prevent frame missing without allocating an extra memory area (buffer area).

### 5. Fifth Embodiment

Next, description will cover a data processing device according to a fifth embodiment of the present invention. Like the first embodiment, this data processing device is also used in the portable terminal having the configuration shown in FIG. 1. The system configuration (the configuration of hardware and software) of the data processing device and the display device included in this portable terminal is the same as in the first embodiment (FIG. 2). Further, the display device and its display control circuit have basically the same configurations as in the first embodiment (FIGS. 3, 4, 5). Therefore, among these hardware and software components of the present embodiment, those which are identical with or corresponding to the components in the first embodiment will be indicated with the same reference symbols, without repeating detailed descriptions thereof.

In the first embodiment, as shown in FIG. 15, the extension portion of the image buffer 12f extended to prevent the frame missing in the returning state of the LCD is released, when a no-update frame period occurs the number of times which corresponds to the return time (the duration of the returning state) in Normal State. In the present embodiment, as a method of releasing the extension portion of the image buffer 12f, a method of temporarily increasing the transfer rate of the display image data to the LCD and the refreshing rate of the display image so as to release the extension state (release the extension portion) is adopted instead of the method (FIG. 15) described in the first embodiment.

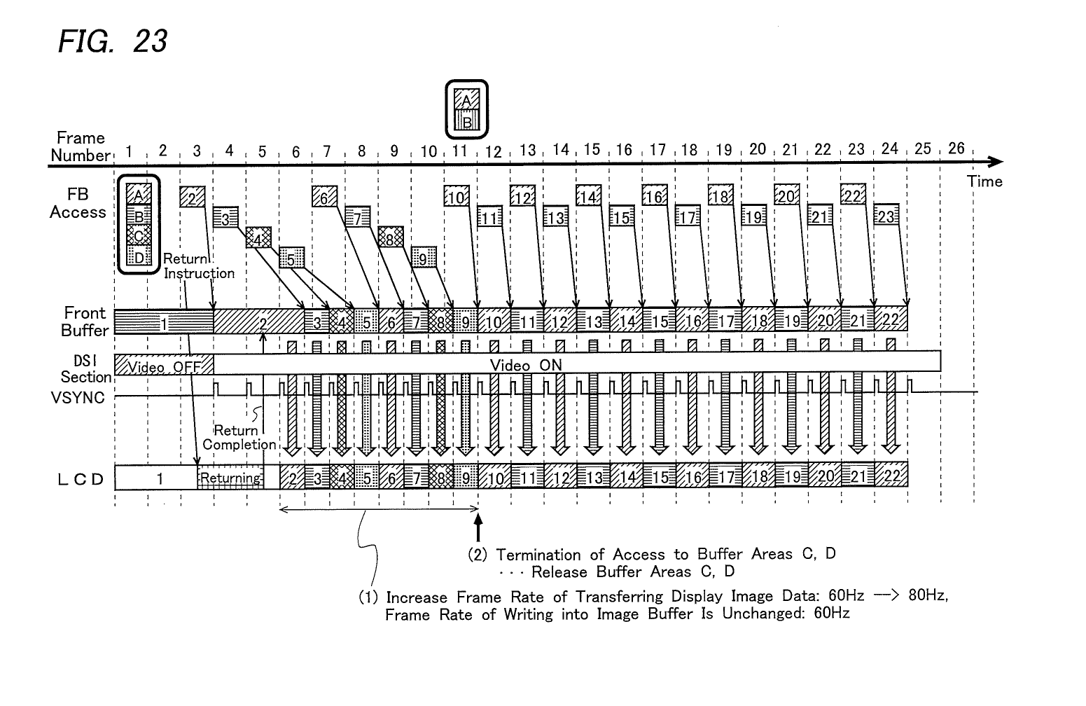

FIG. 23 is a timing chart showing operation related to release of an extension state of the image buffer in the present embodiment. In the example shown in FIG. 23, as in the example shown in FIG. 15, the host and the LCD are in Intermission State 2 during the first and second frame periods, and the image buffer 12f, which is in the extension state, is composed of four FB regions 12fA to 12fD. Of these, the FB area 12fB stores display image data D1 and serves as a front buffer.

During the third frame period, new display image data D2 supplied to the image buffer 12f due to a user operation on the input operation section 16 is written into the FB area 12fA as a back buffer, and a return instruction is sent from the host to the LCD (Steps S60 through S64). Thereafter, the host waits until it receives a return completion notification from the LCD (Step S65).

In the example shown in FIG. 23, the return completion notification is sent from the LCD to the host in the 15th frame period, and no display image data is transferred to the LCD until the 15th frame period. However, also after the fourth frame period, sets of new display image data D 3, D 4, D 5, . . . are sequentially supplied to the image buffer 12f.

In the sixth frame period, transfer of the display image data from the host to the LCD is restarted. While sets of new display image data are supplied to the image buffer 12f due to user operations on the input operation section 16 in and after the sixth frame period, display image data Dj is written into the image buffer 12f including the four FB areas 12fA to 12fD (the image buffer 12f including the extension portion of two frames) and display image data Dj−3 is read from the same (j=5, 6, 7, . . . ) by the first-in first-out method.

In the present embodiment, upon receiving a restart completion notification from the LCD, the host increases the transfer rate of the display image data to the LCD and the refreshing rate of the display image from the next frame period (the sixth frame period in this example). In the present embodiment, the transfer rate and refreshing rate are changed from 60 [frames/sec] to 80 [frames/sec]. However, the writing rate of new display image data into the image buffer 12f is maintained at 60 [frames/sec] and is not changed. For this reason, during the six frame periods from the sixth through eleventh frame periods, while sets of display image data supplied to the image buffer 12f and written into back buffers are data D5 through D10 of six frames, sets of display image data transferred to the LCD and used for refreshing the display image in the LCD are data D2 through D9 of 8 frames. As a result, it is possible to reduce the number of FB areas in the image buffer 12f from four to two at the end of the eleventh frame period. During the eleventh frame period, new display image data D10 is written into the FB area 12fA as a back buffer, and the transfer of the display image data D9 in the FB area 12fD as a front buffer to the LCD is completed.

In this way, in the example of FIG. 23, since the access to the two FB areas 12fD and 12fC as the extension portion of the image buffer 12f is terminated at the end of the eleventh frame period, these FB areas 12fC and 12fD are released and also the transfer rate and the refreshing rate, which have been changed to 80 [frames/sec], are returned to 60 [frames/sec]. From the twelfth frame period, at the standard rate of 60 [frames/second], the display image data is transferred to the LCD and the display image of the LCD is refreshed. In the process of transferring the display image data in the image buffer 12f to the LCD at a higher speed (80 frames/second) than the standard rate (60 frames/second), the twelfth frame period is a frame period in which each set of display image data stored in the FB area 12fC, 12fD as the extension portion has already been read out, neither of the FB areas 12fC, 12fD serves as a front buffer, and new display image data has not been written into the FB areas 12fC, 12fD as the extension portion. Therefore, it may be considered that when such a frame period occurs, the FB areas 12fC and 12fD as the extension portion are released and also the transfer rate and the refreshing rate, which have been changed to 80 [frames/second], are returned to 60 [frames/second].

In the present embodiment, the number of frame periods Nfast during which the transfer rate to the LCD and the display image refresh on the LCD should be performed at a rate (80 frames/second) higher than the standard rate (60 frames/second), that is, the number of frame periods Nfast during which high speed driving is to be performed can be generally obtained by the following equation:

Nfast=(Ffast*Ndelay)/(Ffast−Forig) (1)

where Ffast is a frequency of the high speed driving, Forig is a frequency when the LCD is driven at the standard rate (a frequency of standard speed driving), and Ndelay is the number of frames for which the extension of the image buffer 12f causes delay. In the above equation (1), “*” is a symbol indicating multiplication. In the example shown in FIG. 23, the high-speed drive frequency corresponds to the high transfer rate (80 frames/second), the standard drive frequency corresponds to the standard transfer rate (60 frames/second), Ffast=80 Hz, Forgin=60 [Hz], Ndelay=2, so Nfast=8 [frame period].

During the 12th frame period and each frame period thereafter, while sets of new display image data are supplied to the image buffer 12f due to user operations on the input operation section 16, new display image data Di+1 is written into a back buffer and also the display image data Di written into a back buffer during the preceding frame period is transferred to the LCD (i=10, 11, 12, . . . ). It should be noted here that since the image buffer 12f is composed of the two FB regions 12fA and 12fB, one FB area as a back buffer and the other FB area as a front buffer are alternately switched between the two FB areas 12fA and 112fB.

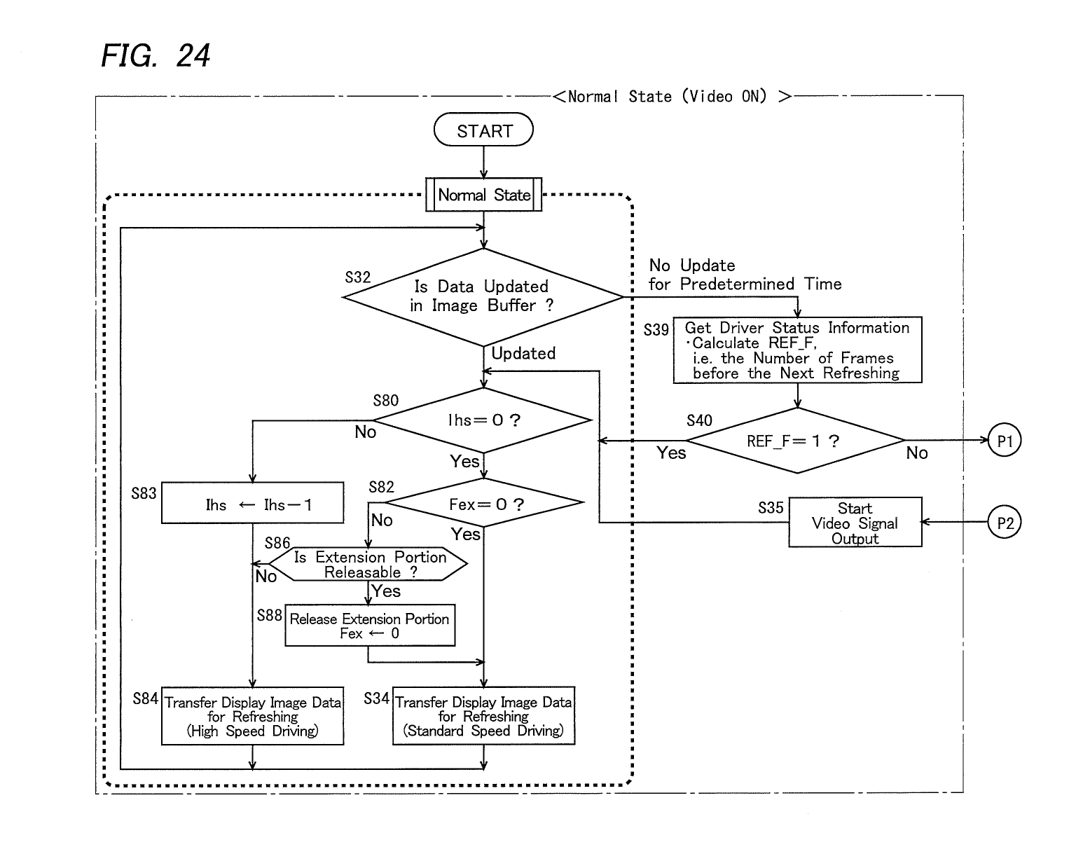

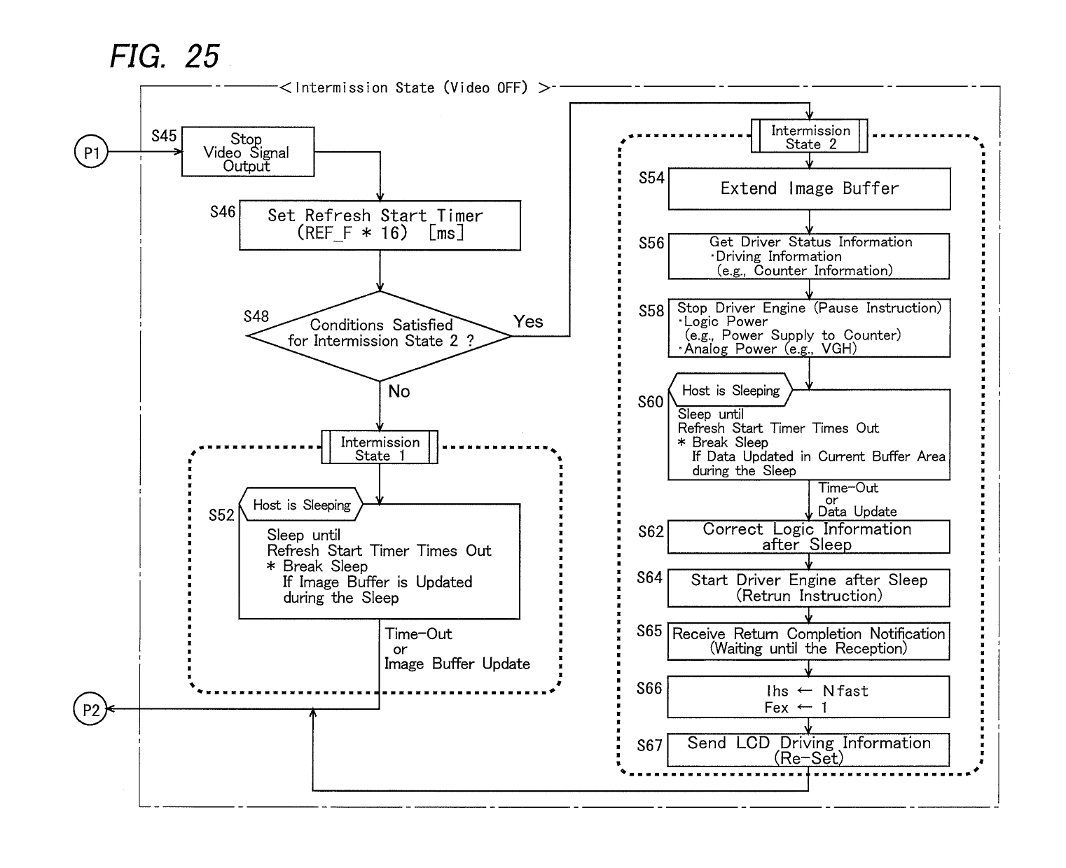

Next, the processing procedure of the DSI controller 135 (see FIG. 2) in the present embodiment as described above will be described. FIG. 24 is a flowchart showing a processing procedure of the DSI controller 135 in Normal State, and FIG. 25 is a flowchart showing a processing procedure of the DSI controller 135 for shifting from Normal State to Intermission State 1 or 2 and a processing procedure of the DSI controller 135 for shifting from Intermission State 1 or 2 to Normal State (that is, a processing procedure of the DSI controller 135 for Intermission State). When the data processing device 100 as the host is started, the CPU 101 operates as shown in FIGS. 24 and 25, whereby the DSI controller 135 is implemented as a process in the kernel space. The procedure of processing executed by the CPU 101 to implement the update detection section 132 (see FIG. 2) in the present embodiment, i.e., the processing procedure in the timer interrupt handler is the same as the processing procedure for implementing the update detection section 132 in the first embodiment, except that the processing procedure in the timer interrupt handler does not include the steps related to the second no-update variable Jnup, and therefore its description will be omitted.

In the processing procedure of the DSI controller 135 in the present embodiment, there are introduced a drive frequency control variable Ihs for controlling switching between the high-speed driving and the standard speed driving as described above and an extension state flag Fex indicating whether or not the image buffer 12f is in an extension state, and the drive frequency control variable Ihs and the extension state flag Fex are initialized to “0” at starting of the data processing device 100.

As shown in FIG. 24, in the present embodiment, when the data processing device 100 is started, the CPU 101 determines whether or not the display image data is updated in the image buffer 12f (FIG. 9) as in the first embodiment (Step S32). As a result of this judgment, when the display image data is updated in the image buffer 12f, it is judged whether or not the drive frequency control variable Ihs is “0” (Step S80). Immediately after starting of the data processing device 100, Ihs=0. In this case, it is determined whether or not the extended state flag Fex is “0” (Step S82). Immediately after starting of the data processing device 100, Fex=0, and in this case, the process proceeds to Step S34. In Step S34, the display image data in (a front buffer of) the image buffer 12f is transferred to the display device 11 at the standard rate (60 frames/second) by the DSI section 106, and thereafter the process returns to Step S32. Upon receiving the display image data, the display device 11 refreshes the display image by displaying an image represented by the display image data in the display section 600 as in the first embodiment (see FIGS. 3 and 5).

As a result of the determination in Step S32, if the display image data is not updated in the image buffer 12f (more accurately, when the display image data has not been updated for a predetermined time), the process proceeds to Step S39, obtains driver status information (LCD drive information) in the display device 11 and calculates the number of frames preceding the next refreshing of the display image, that is, the refreshing start preceding frame count REF_F, based on the acquired LCD drive information.

Next, it is determined whether or not the refreshing start preceding frame count REF_F is “1” (Step S40). As a result of this determination, if the refreshing start preceding frame count REF_F is “1”, the process proceeds to the aforementioned Step S80. On the other hand, as a result of this determination, if the refreshing start preceding frame count REF_F is not “1”, that is, if it is “2” or more, the process proceeds to Step S45 in FIG. 25 so as to bring the DSI controller 135 into a sleep state.

If the process proceeds to step S45 in FIG. 25, it is considered that the display device 11 is operating in the intermission driving mode and is displaying a still image, and therefore causes the DSI portion 106 to stop transferring display image data to the display device 11 (stop of video signal output). Thereafter, substantially the same processing as in the first embodiment (FIG. 10) is performed. Therefore, in the processing procedure shown in FIG. 25, the same steps as those shown in FIG. 10 are denoted by the same step numbers, without repeating descriptions thereof, and only the differences will be described.

In the processing procedure shown in FIG. 25, after receiving a return completion notification from the LCD at Step S65, unlike the processing procedure shown in FIG. 10, a value preset as the number of frame periods Nfast during which the high speed driving is to be performed (the value determined by the aforementioned equation (1), which is “8” in the present embodiment) is assigned to the driving frequency control variable Ihs and “1” is assigned to the extension state flag Fex (Step S66). Further, in the processing procedure shown in FIG. 25, Step S68 (the step relating to the second no-update variable Jnup) in the processing procedure shown in FIG. 10 is deleted.

According to the above-described Step S66, in the present embodiment, the value of the drive frequency control variable Ihs is equal to the number of frame periods Nfast and the value of the extension state flag Fex is “1” at the time of returning from Intermission State 2 to Normal State.

In the present embodiment, when returning from Intermission State 1 or Intermission State 2 to Normal State, the processing proceeds from Step S52 or S67 shown in FIG. 25 to Step S35 shown in FIG. 24, and causes the DSI section 106 to resume its operation for transferring display image data to the display device 11 (start of video signal output). Thereafter, the process proceeds to the aforementioned Step S80.

When returning from Intermission State 1 to the normal state, both the values of the driving frequency control variable and the extension state flag Fex are normally “0”, and therefore operation after Step S80 is as described above.

When returning from Intermission State 2 to Normal State, the driving frequency control variable Ihs=Nfast≠0 (see Step S66), and therefore the process proceeds to Step S83, in which the value of the driving frequency control variable Ihs is decremented by 1. Subsequently, the display image data in (a front buffer of) the image buffer 12f is transferred to the display device 11 at the high speed (80 frames/second) (Step S84), and then the process returns to Step S32. Thereafter, when a data update in the image buffer 12f continues due to user operations on the input operation section 16 on the host side, writing of moving image data into the image buffer 12f, etc., Steps S32→S80→S83→S84 (transfer of display image data at the high speed) are repeatedly executed until the drive frequency control variable Ihs becomes “0”. When the drive frequency control variable Ihs becomes “0”, the process proceeds to Step S82.

Since the value of the extension state flag Fex is “1” at this time point (see Step S66), the process proceeds to Step S86, and it is determined whether or not the extension portion of the image buffer 12f extended in Step S54 in Intermission State 2 (the FB areas 12fC and 12fD in the present embodiment (see FIG. 7)) are releasable. Here, when each set of display image data stored in the FB areas 12fC, 12fD as the extension portion has already been read out and new image data has not been written into the FB areas 12fC, 12fD, that is, when all the display image data stored in the areas 12fC, 12fD has already been transferred to the LCD and neither of the FB areas 12fC, 12fD serves as a front buffer, it is determined to be releasable, and otherwise, it is determined to be unreleasable.

If the extension portion of the image buffer 12f is releasable as a result of the determination in Step S86, the FB areas 12fC, 12fD as the extension portion are released (release of the extension state), and the extension state flag Fex is set to “0” (Step S88). Thereafter, the process proceeds to Step S34, and the display image data in (a front buffer of) the image buffer 12f is transferred to the LCD at the standard rate (60 frames/second), and the process returns to Step S32. Thereafter, since Ihs=Fex=0 until the next transition to Intermission State 2, display image data in the image buffer 12f is transferred to the LCD at the standard rate (60 frames/second) every time display image data is updated in the image buffer 12f (Step S32→S80→S82→S34).

According to the present embodiment as described above, as shown in FIG. 23, the extension state of the image buffer 12f extended to prevent frame missing in the returning state of the LCD is released by increasing the transfer rate of the display image data to the LCD and the refreshing rate of the display image of the LCD from the frame period immediately after receiving a return completion notification from the LCD (see Steps S65, S66 in FIG. 25, and Steps S80, S83, S84 in FIG. 24). Therefore, even in the case of continuing data update in the image buffer 12f, such as in the case of reproducing a moving image, the extension portion in the FB areas is certainly released after a predetermined time since the LCD returns to Normal State, and delay in refreshing the display image can be eliminated. It should be noted here that the transfer rate and the refreshing rate after receiving a return completion notification from the LCD are not limited to 80 [frames/sec], and only need be higher than the writing rate of new display image data into a back buffer in the image buffer 12f. If the transfer rate and the refreshing rate after the return completion notification is increased, the delay in refreshing the display image can be eliminated promptly, and if the transfer rate is lowered, the refreshing rate change is hardly perceived by the user so that the refresh delay can be solved naturally.

### 6. Sixth Embodiment

In each of the above-described embodiments, the intermission state of the host 100 and the display device 11 (LCD) is provided as an intermission state of two stages consisting of the Intermission State 1 and Intermission State 2. However, the present invention is applicable to a case where the LCD requires time (for example, one frame period or more) to return from the intermission state to the normal state even in a configuration in which the intermission state is changed to only one stage in each of the above embodiments. Therefore, in the following, an example of a data processing device having such a configuration will be described as a sixth embodiment of the present invention.

The data processing device according to the present embodiment is also used in a portable terminal configured as shown in FIG. 1 as in the first embodiment. The system configuration (the configuration of hardware and software) of the data processing device and the display device included in this portable terminal is the same as in the first embodiment (FIG. 2). Further, the display device and its display control circuit have basically the same configurations as the first embodiment (FIGS. 3, 4, 5). Therefore, among these hardware and software components of the present embodiment, those which are identical with or corresponding to the components in the first embodiment will be indicated with the same reference symbols, without repeating detailed descriptions thereof.

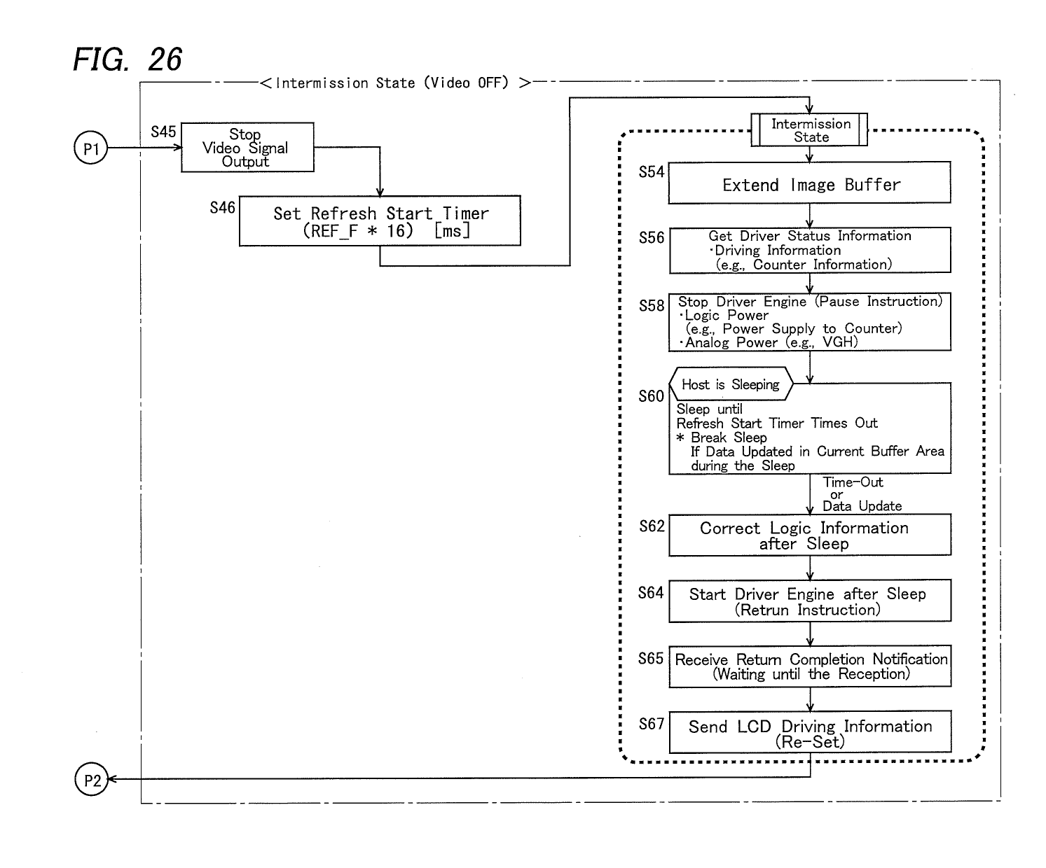

The present embodiment is configured to have only one intermission state corresponding to Intermission State 2 in the first embodiment as an intermission state of the data processing device 100 (host) and the display device 11 (LCD). Therefore, in the present embodiment, the processing procedure of the DSI controller 135 for the intermission state is a procedure shown in FIG. 26, in which Steps S48 and S52 are removed from the processing procedure in the first embodiment shown in FIG. 10. The configuration of the video driver 131 (the configuration of the update detection section 132, the FB access processing section 133, and the DSI controller 135) is the same as that of the first embodiment except that the processing procedure of the DSI controller 135 is partially different therefrom.

Operation in the present embodiment is also the same as in the first embodiment except for the difference due to having only the intermission state corresponding to Intermission State 2 in the first embodiment as an intermission state of the host and the LCD. Therefore, FIG. 6, FIG. 7, (B) of FIG. 12, FIG. 14, and FIG. 15 related to the first embodiment can be respectively regarded as being a block diagram for describing writing/reading display image data into/from the image buffer 12f in an unextension state, a block diagram for describing writing/reading display image data into/from the image buffer 12f in an extension state, a sequence diagram for describing operation of the host's shifting from the normal state to the intermission state, a timing chart showing operation related to update and transfer of display image data, and a timing chart showing operation related to release of an extension state of the image buffer. Therefore, Detailed descriptions of the operation in the present embodiment will be omitted.

Also in the present embodiment as described above, the image buffer 12f is extended (FIG. 6→FIG. 7, FIG. 14) when shifting from the normal state to the intermission state, and the image buffer 12f in the extension state is released when a no-update frame period occurs a predetermined number of times (FIG. 7→FIG. 6, FIG. 15) in the normal state. Therefore, the same advantages as in the first embodiment is obtained (FIG. 17, etc.)

### 7. Variations

The present invention is not limited to any of the embodiments described above, but may be varied in many ways within the scope of the present invention. The present invention also includes any combinations of a plurality of the embodiments described thus far, as far as there is no conflict arising from the combination.

For example, although the image buffer 12f is composed of one front buffer and one or more back buffers (FIGS. 6 and 7) in each of the above-described embodiments, it may be of any other configuration as long as display image data can be written and read out by the first-in first-out method and the image buffer 12f is extensible and its extension portion is releasable. It should be noted here that it is necessary to have such a configuration that if display image data is to be transferred to the LCD after display image data has been read from the image buffer 12f before new display image data is supplied thereto, the display image data most recently read from the image buffer 12f is read therefrom again (see the eighth frame period in FIG. 14, etc., for example).

In the case of measuring duration of a returning state of the LCD as return time like the fourth embodiment, when returning from Intermission State (Intermission State 2) to Normal State, transfer of the display image data from the host to the LCD may be resumed at timing based on the return time measurement value without waiting for a return completion notification from the LCD. This simplifies the operation and configuration for returning from Intermission State 2 to Normal State and makes it possible to reduce the delay in refreshing the displayed image on the LCD.

In each of the above embodiments, the interface based on the MIPI-DSI standard, or the interface conforming to the I2C standard or the SPI standard is used for a return completion notification to the host when the LCD returns from Intermission State 2 to Normal State (FIGS. 2 and 8). Instead, the I/O port of the data processing device 100 as the host or the CPU 101 may be used. In this case, it can be configured that a signal line is connected so that status output of the LCD is supplied to the I/O port, for example, a low level signal is supplied to the I/O port when the LCD is in the intermission state or the returning state, a low level signal is supplied to the I/O port when the LCD is in the operating state (a state in which driving for refreshing the display image can be performed), and the host operates the DSI section 106 (Video ON) when the signal supplied to the I/O port is high level.

In each of the embodiments, means for managing the next refreshing timing of display image in the LCD based on monitoring presence/absence of display image data update in the image buffer 12f is implemented in the host as a component of the video driver 131 which operates in the kernel space, as shown in FIG. 2. However, the present invention is not limited to this. For example, part of the means may be implemented as a component within the AP frame work.

### 8. Others

Although each embodiment has been described by using a portable terminal as an example (FIG. 1), the present invention is not limited to this, and is applicable to any data processing device used for an electronic appliance if a frame buffer is provided on the host side. Also, the display device to be connected with the data processing device according to the present invention may be any display device that performs intermission driving. In other words, the present invention is also applicable to electronic appliances which make use of display devices other than liquid crystal display devices (LCDs), such as an organic EL (Electro Luminescence) display device.

The present application claims priority based on Japanese Patent Application No. 2015-205672 filed on Oct. 19, 2015 entitled “DATA PROCESSING DEVICE TO WHICH DISPLAY DEVICE IS CONNECTED, AND CONTROL METHOD FOR DISPLAY DEVICE”, the contents of which are incorporated herein by reference.

### INDUSTRIAL APPLICABILITY

The present invention is applicable to data processing devices connected with display devices which perform so called intermission driving, and to method for controlling these display devices in these data processing devices.

### DESCRIPTION OF REFERENCE CHARACTERS

10 Main Controller
11 Display Device (LCD, LCD Module)
12 Memory Section
12f Image Buffer
12fC, 12fD FB Area (Extension Frame Buffer Area)
16 Input Operation Section
31 Interface Section
31a DSI Communication Section
35 Timing Generator
35a Counter
37 Command Register
39 Built-in Power Supply Circuit
40 LCD Driving Section
60 Liquid Crystal Display Panel
100 Data Processing Device (Host)
101 Application Processor (CPU)
106 DSI Section (First Interface Circuit)
107 I2C/SPI Section (Second Interface Circuit)
120 Application Frame Work (AP Frame Work)
130 Operating System (OS)
131 Video Driver
132 Update Detection Section
133 FB Access Processing Section
135 DSI Controller (Interface Controller)
136 IF controller (Interface Controller)
200 Display Control Circuit
310 Data Signal Line Drive Circuit
320 Scanning Signal Line Drive Circuit
600 Display Section

1: A data processing device connected data-exchangeably with a display device having an intermission driving mode, in which the display device drives a display section in such a manner that a refreshing period during which an image displayed in the display section is refreshed and a non-refreshing period during which an image displayed in the display section is not refreshed are alternated with each other, the data processing device comprising:
a memory section capable of storing image data for a plurality of frames each representing an image to be displayed in the display section, the memory section having, as an image buffer, a memory area including at least one frame buffer area;
an update detection section configured to detect a data update of image data in the image buffer, the data update being caused by writing of new image data into the image buffer;
a data transfer controller configured to transfer image data stored in the image buffer to the display device by a first-in first-out method upon detection of a data update in the image buffer by the update detection section, and assume an intermission state for an intermission period determined as the non-refreshing period at most upon detection of a non-update of the image data in the image buffer for a predetermined time by the update detection section;
wherein the data transfer controller is configured to
extend the memory area of the memory section when the data transfer controller shifts to the intermission state, and
return to a normal state, in which the data transfer controller transfers the image data to the display device in response to a data update detected by the update detection section, as well as send a return instruction for operating a stopped circuit in the display device to the display device, upon detection of a data update in the image buffer by the update detection section in the intermission state.

2: The data processing device according to claim 1, wherein, if the memory area of the image buffer has been extended, the data transfer controller
counts, as a non-update frame period count, the number of frame periods during which the update detection section detects that there is no data update in the image buffer in the normal state, and
releases an extension frame buffer area defined as an extension portion of the image buffer when the non-update frame period count becomes larger than the number of frame periods corresponding to a return time defined as time from sending of the return instruction to the display device till resuming of operation of the stopped circuit in the display device.

3: The data processing device according to claim 1, wherein the data transfer controller
sends a return instruction for operating the stopped circuit in the display device to the display device when the data transfer controller returns from the intermission state to the normal state,
transfers the image data in the image buffer to the display device at a second transfer rate higher than a first transfer rate predetermined as a standard rate when the data transfer controller receives a return completion notification indicating resumption of operation of the stopped circuit in the display device from the display device after sending the return instruction,
releases an extension frame buffer area defined as an extension portion of the image buffer and changes a transfer rate of the image data in the image buffer to the first transfer rate, when there occurs a frame period in which image data stored in the extension frame buffer area has already been read out and new display image data has not been written into the extension frame buffer area while the image data in the image buffer is transferred to the display device at the second transfer rate.

4: The data processing device according to claim 3, wherein, upon receiving the return completion notification from the display device, the data transfer controller transfers the image data in the image buffer to the display device at the second transfer rate for time corresponding to the number of frame periods given by the following equation:
Nfast=(Ffast*Ndelay)/(Ffast−Forig)
where Ffast is the second transfer rate, Forig is the first transfer rate, Ndelay is the number of frames for which the extension of the memory area of the image buffer causes delay.

5: The data processing device according to claim 1, wherein the data transfer controller
sends a return instruction for operating the stopped circuit in the display device to the display device, upon returning from the intermission state to the normal state,
determines a return time measurement value by measuring time from sending the return instruction till receiving a return completion notification indicating resumption of operation of the stopped circuit in the display device, and determines or changes a size of an extension frame buffer area defined as an extension portion of the image buffer, upon receiving the return completion notification after sending the return instruction.

6: The data processing device according to claim 5, wherein, when the data transfer controller sends the return instruction to the display device after determining the return time measurement value, the data transfer controller starts transferring the image data in the image buffer to the display device at timing based on the return time measurement value without waiting for the return completion notification to be received from the display device after sending the return instruction.

7: The data processing device according to claim 1, wherein the data transfer controller
determines the intermission period based on refreshing-related information obtained from the display device, when the update detection section detects a non-update of the image data in the image buffer for the predetermined time,
shifts to the intermission state if the intermission period is longer than a predetermined reference period,
stops a first circuit defined as a circuit which has time required for resuming operation not longer than a predetermined time among circuits to be stopped in the display device in the intermission state and thereafter shifts to a short intermission state different from the intermission state without extending the memory area of the image buffer, if the intermission period is not longer than the predetermined reference period, and
returns to the normal state and resumes operation of the first circuit in the display device, when the update detection section detects a data update in the image buffer while the data transfer controller is in the short intermission state.

8: The data processing device according to claim 1, wherein the data transfer controller includes:
a first interface circuit configured to transfer image data in the image buffer to the display device, and
a second interface circuit configured to send a return instruction for operating the stopped circuit in the display device to the display device and receive a return completion notification indicating resumption of operation of the stopped circuit in the display device from the display device, when the data transfer controller returns from the intermission state to the normal state,
wherein the second interface circuit is provided as a serial interface having a slower data transfer rate than the first interface circuit.

9: The data processing device according to claim 1, wherein the display section includes a thin film transistor having a channel etch structure which has a channel layer formed of an oxide semiconductor, as a switching element for forming each pixel constituting an image to be displayed.

10: The data processing device according to claim 9, wherein the oxide semiconductor is provided by In—Ga—Zn—O.

11: The data processing device according to claim 10, wherein the oxide semiconductor is provided by a crystalline In—Ga—Zn—O.

12: A method for enabling a data processing device to control a display device which is connected data-exchangeably therewith and has an intermission driving mode, in which the display device drives a display section in such a manner that a refreshing period during which an image displayed in the display section is refreshed and a non-refreshing period during which an image displayed in the display section is not refreshed are alternated with each other, the method comprising:
an update detection step of detecting an update of image data in an image buffer in a memory section within the data processing device, the memory section being capable of storing image data for a plurality of frames each representing an image to be displayed in the display section, the memory section having, as the image buffer, a memory area including at least one frame buffer area;
an updated-data transfer step of transferring image data stored in the image buffer to the display device by a first-in first-out method upon detection of a data update in the image buffer;
an intermission step of assuming an intermission state for an intermission period determined as the non-refreshing period at most, upon detection of a non-update of the image data in the image buffer for a predetermined time;
a buffer extension step of extending the memory area of the image buffer upon shifting to the intermission state;
a return instruction step of sending a return instruction for operating a stopped circuit in the display device to the display device, upon detection of a data update in the image buffer in the intermission state; and
a return-to-normal-state step of returning to a normal state, in which the image data is transferred to the display device in response to a data update detected in the update detection step, upon detection of a data update in the image buffer in the intermission state.

13. (canceled)

14: A non-transitory computer-readable recording medium containing a device driver program for enabling a data processing device to control a display device which is connected data-exchangeably therewith and has an intermission driving mode, in which the display device drives a display section in such a manner that a refreshing period during which an image displayed in the display section is refreshed and a non-refreshing period during which an image displayed in the display section is not refreshed are alternated with each other, the program causing a processor in the data processing device to execute:
an update detection step of detecting an update of image data in an image buffer in a memory section within the data processing device, the memory section being capable of storing image data for a plurality of frames each representing an image to be displayed in the display section, the memory section having, as the image buffer, a memory area including at least one frame buffer area;
an updated-data transfer step of transferring image data stored in the image buffer to the display device by a first-in first-out method upon detection of a data update in the image buffer;
an intermission step of assuming an intermission state for an intermission period determined as the non-refreshing period at most, upon detection of a non-update of the image data in the image buffer for a predetermined time;
a buffer extension step of extending the memory area of the image buffer upon shifting to the intermission state;
a return instruction step of sending a return instruction for operating a stopped circuit in the display device to the display device, upon detection of a data update in the image buffer in the intermission state; and
a return-to-normal-state step of returning to a normal state, in which the image data is transferred to the display device in response to a data update detected in the update detection step, upon detection of a data update in the image buffer in the intermission state.
